(19) United States
(12) Patent Application Publication
(10) Pub. No.: US 2026/0226603 A1
(43) Pub. Date: Aug. 6, 2026

(54) Heat-Treatable Coating with Blocking Layer Having Reduced Color Shift

(71) Applicant: Vitro Flat Glass LLC, Cheswick, PA (US)

(72) Inventors: Sudarshan Narayanan, Kanpur (IN); Ashtosh Ganjoo, Allison Park, PA (US); Adam D. Polcyn, Pittsburgh, PA (US)

(21) Appl. No.: 19/635,945

(22) Filed: Apr. 1, 2026

Related U.S. Application Data
(62) Division of application No. 17/504,968, filed on Oct. 19, 2021.
(60) Provisional application No. 63/094,584, filed on Oct. 21, 2020.

(51) Int. Cl. C23C 14/02; C23C 14/06; C23C 14/08; C23C 14/18; C23C 14/35; G02B 5/20

(52) U.S. Cl. CPC C23C 14/024; C23C 14/0652; C23C 14/0676; C23C 14/081; C23C 14/086; C23C 14/185; C23C 14/35; G02B 5/208; Y10T 428/265

(57) ABSTRACT

A coated article includes a substrate with a first surface and a second surface and a functional coating applied over the first surface or the second surface. The functional coating includes a blocking layer over at least a portion of the substrate; a metallic layer over at least a portion of the blocking layer; and a top layer over at least a portion of the metallic layer. The coated article has an optical color shift, as measured by ΔEcmc, of no more than 4.5 after tempering.

### CROSS-REFERENCE TO RELATED APPLICATION

This application is a divisional application of U.S. patent application Ser. No. 17/504,968 filed Oct. 19, 2021, which claims priority to U.S. Provisional Application No. 63/094,584, filed on Oct. 21, 2020, the disclosures of which are incorporated by reference herein in their entireties.

### BACKGROUND OF THE INVENTION

### Field of the Invention

This invention relates to a blocking layer and, more particularly, to a blocking layer to prevent diffusion of alkali metal, alkaline earth metal ions, and metal ions, such as, sodium ions, from a glass substrate into a medium (e.g., a coating such as, a solar control coating), or from a medium (e.g., a coating such as a solar control coating) into a glass substrate.

### Technical Considerations

Solar control coatings are known in the fields of architectural and vehicle transparencies. These solar control coatings block or filter selected ranges of electromagnetic radiation, such as, in the range of solar infrared or solar ultraviolet radiation, to reduce the amount of solar energy entering the vehicle or building. This reduction of solar energy transmittance helps reduce the load on the cooling units of the vehicle or building.

These solar control coatings typically include one or more continuous metal layers to provide solar energy reflection, particularly in the solar infrared region. Metal layers deposited below a critical thickness (referred to herein as “subcritical layers”) form discontinuous regions or islands rather than a continuous layer. These discontinuous layers absorb electromagnetic radiation through an effect known as surface Plasmon resonance. These subcritical layers typically have higher absorbance in the visible region than a continuous layer of the same material and also have lower solar energy reflectance.

Upon heating coated articles with solar control coatings, an undesirable color shift can occur due to the changes in the optical properties of the layers of the solar control coating. It would be desirable to produce a solar control coating in which the absorption of the coating and/or the color of the coated article could be maintained before heating and after heating.

### SUMMARY OF THE INVENTION

The invention relates to a coated article comprising a substrate. The substrate comprises a first surface and a second surface opposite the first surface. A functional coating is applied over the first surface or the second surface. A blocking layer is positioned over at least a portion of the substrate. A metallic layer is positioned over at least a portion of the blocking layer. A top layer is positioned over at least a portion of the metallic layer.

The invention relates to a coated article comprising a substrate comprising a first surface and second surface opposite the first surface. A functional coating is applied over the first surface or the second surface. A blocking layer is positioned over at least a portion of the substrate, wherein the blocking layer comprises a first film, a second film, and third film, wherein the first film of the blocking layer is a blocking film; wherein the blocking film comprises silicon oxide, silicon aluminum oxide, silicon oxynitride, silicon aluminum oxynitride, or a combination thereof. A metallic layer is positioned over at least a portion of the blocking layer. A top layer over is positioned over at least a portion of the metallic layer. The coated article is temperable.

The invention relates to a method of making a coated article comprising a substrate. A substrate comprising a first surface and a second surface opposite the first surface is provided. A blocking layer is formed over at least a portion of the first surface or the second surface. A metallic layer is formed over at least a portion of the blocking layer. A top layer is formed over at least a portion of the metallic layer. The coated article has an optical color shift, as measured by ΔEcmc, of no more than 4.5 after tempering.

The invention relates to a method of making a coated article. A coated article comprising a first surface and second surface opposite the first surface is provided. The coated article comprises a blocking layer over at least a portion of the first surface or the second surface, a metallic layer over at least a portion of the blocking layer, and a top layer over at least a portion of the metallic layer. The coated article is tempered. The coated article has an optical color shift, as measured by ΔEcmc, of no more than 4.5 after tempering.

The invention relates to an insulated glass unit comprising a first ply and a second ply. The first ply comprises a No. 1 surface and a No. 2 surface opposing the No. 1 surface. The second ply comprises a No. 3 surface and a No. 4 surface. The second ply is spaced from the first ply and the first ply and second ply are connected together. A functional coating is positioned over at least a portion of the No. 3 surface or the No. 4 surface. A blocking layer is positioned over at least a portion of the No. 3 surface or the No. 4 surface. A metallic layer is positioned over at least a portion of the blocking layer. A top layer is positioned over at least a portion of the metallic layer.

The invention relates to a method of reducing dendrite formation in a metallic layer of a coated article. A substrate comprising a first surface and second surface opposite the first surface is provided. A blocking layer is formed over at least a portion of the first surface or the second surface. A metallic layer is formed over at least a portion of the blocking layer. A top layer is formed over at least a portion of the metallic layer, thereby forming the coated article. The coated article is tempered. The coated article has reduced dendrite formation in the metallic layer after tempering.

The invention relates to a method of reducing dendrite formation in a metallic layer of a coated article. A coated article comprising a first surface and second surface opposite the first surface is provided. The coated article comprises a blocking layer over at least a portion of the first surface or the second surface, a metallic layer over at least a portion of the blocking layer, and a top layer over at least a portion of the metallic layer. The coated article is tempered. The coated article has reduced dendrite formation in the metallic layer after tempering.

The invention relates to a method of reducing red haze of a coated article. A substrate comprising a first surface and second surface opposite the first surface is provided. A blocking layer is formed over at least a portion of the first surface or the second surface. A metallic layer is formed over at least a portion of the blocking layer. A top layer is formed over at least a portion of the metallic layer, thereby forming the coated article. The coated article is tempered. The coated article has reduced red haze after tempering.

The invention relates to a method of reducing red haze of a coated article. A coated article comprising a first surface and second surface opposite the first surface is provided. The coated article comprises a blocking layer over at least a portion of the first surface or the second surface, a metallic layer over at least a portion of the blocking layer, and a top layer over at least a portion of the metallic layer. The coated article is tempered. The coated article has reduced red haze after tempering.

### BRIEF DESCRIPTION OF THE DRAWINGS

FIG. 1A is a side view (not to scale) of an exemplary insulating glass unit (“IGU”) having a coating of the invention.

FIG. 1B is a sectional view of an exemplary transparency having a coating of the invention.

FIGS. 2A, 2B, and 2C is a sectional view (not to scale) of a single metal coating according to an example of the invention. FIG. 2A is a single metal coating comprising a substrate, a blocking layer, a metallic layer, a primer layer, a top layer, and a protective coating. FIG. 2B is the single metal coating of FIG. 2A depicting the blocking layer comprising three films, the top layer comprising two films, and a protective coating comprising two films. FIG. 2C is the single metal coating of FIG. 2A depicting the blocking layer comprising three films, the top layer comprising three films, and a protective coating comprising two films.

FIGS. 3A, 3B, and 3C is a sectional view (not to scale) of a double metal coating according to an example of the invention. FIG. 3A is a double metal coating comprising a substrate, a blocking layer, a metallic layer, a primer layer, a first middle layer, a second metallic layer, a primer layer, a top layer, and a protective coating. FIG. 3B is the double metal coating of FIG. 3A depicting the blocking layer comprising three films, the first middle layer comprising three films, the top layer comprising two films, and a protective coating comprising two films. FIG. 3C is the double metal coating of FIG. 3A depicting the blocking layer comprising three films, the first middle layer comprising three films, the top layer comprising three films, and a protective coating comprising two films.

FIGS. 4A, 4B, and 4C is a sectional view (not to scale) of a triple metal coating according to an example of the invention. FIG. 4A is a triple metal coating comprising a substrate, a blocking layer, a metallic layer, a primer layer, a first middle layer, a second metallic layer, a second primer layer, a second middle layer, a third metallic layer, a third primer layer, a top layer, and a protective coating. FIG. 4B is the triple metal coating of FIG. 4A depicting the blocking layer comprising three films, the first middle layer comprising three films, the second middle layer comprising three films, the top layer comprising two films, and a protective coating comprising two films. FIG. 4C is the triple metal coating of FIG. 4A depicting the blocking layer comprising three films, the first middle layer comprising three films, the second middle layer comprising three films, the top layer comprising three films, and a protective coating comprising two films.

FIGS. 5A, 5B, and 5C is a sectional view (not to scale) of a quadruple coating according to an example of the invention. FIG. 4A is a quadruple metal coating comprising a substrate, a blocking layer, a metallic layer, a primer layer, a first middle layer, a second metallic layer, a second primer layer, a second middle layer, a third metallic layer, a third primer layer, a third middle layer, a fourth metallic layer, a fourth primer layer, a top layer, and a protective coating. FIG. 5B is the quadruple metal coating of FIG. 5A depicting the blocking layer comprising three films, the first middle layer comprising three films, the second middle layer comprising three films, the third middle film comprising three films, the top layer comprising two films, and a protective coating comprising two films. FIG. 5C is the quadruple metal coating of FIG. 5A depicting the blocking layer comprising three films, the first middle layer comprising three films, the second middle layer comprising three films, the third middle layer comprising three films, the top layer comprising three films, and a protective coating comprising two films.

FIG. 6 is a graphical representation of color shifts for glass substrates coated with a functional coating having a blocking layer. The blocking layer has a blocking film of silicon aluminum nitride (SiAlN), silicon aluminum oxynitride (SiAlON), or silicon aluminum oxide (SiAlO) at varying thicknesses. The baseline glass substrate has a first dielectric layer having no blocking film.

### DESCRIPTION OF THE INVENTION

As used herein, spatial or directional terms, such as “left”, “right”, “inner”, “outer”, “above”, “below”, and the like, relate to the invention as it is shown in the drawing figures. However, it is to be understood that the invention can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims may vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. “A” or “an” refers to one or more.

Further, as used herein, the terms “formed over”, “deposited over”, or “provided over” mean formed, deposited, or provided on but not necessarily in contact with the surface. For example, a coating layer “formed over” a substrate does not preclude the presence of one or more other coating layers or films of the same or different composition located between the formed coating layer and the substrate. Additionally, all documents, such as, but not limited to, issued patents and patent applications, referred to herein are to be considered to be “incorporated by reference” in their entirety. As used herein, the term “film” refers to a coating region of a desired or selected coating composition. A “layer” can comprise one or more “films”, and a “coating” or “coating stack” can comprise one or more “layers”. The term “asymmetrical reflectivity” means that the visible light reflectance of the coating from one side is different than that of the coating from the opposite side. The term “critical thickness” means a thickness above which a coating material forms a continuous, uninterrupted layer and below which the coating material forms discontinuous regions or islands of the coating material rather than a continuous layer. The term “subcritical thickness” means a thickness below the critical thickness such that the coating material forms isolated, non-connected regions of the coating material. The term “islanded” means that the coating material is not a continuous layer but, rather, that the material is deposited to form isolated regions or islands.

For purposes of the following discussion, the coated articles described herein may be discussed with reference to use with an architectural transparency, such as, but not limited to, an insulating glass unit (IGU). As used herein, the term “architectural transparency” refers to any transparency located on a building, such as, but not limited to, windows and sky lights. However, it is to be understood that the coated articles described herein are not limited to use with such architectural transparencies but, could be practiced with transparencies in any desired field, such as, but, not limited to, laminated or non-laminated residential and/or commercial windows, insulating glass units, and/or transparencies for land, air, space, above water and underwater vehicles. In one aspect or embodiment, the coated articles as described herein are transparencies for use in a vehicle, such as, a window or a sunroof. Therefore, it is to be understood that the specifically disclosed exemplary aspects or embodiments are presented simply to explain the general concepts of the invention, and that the invention is not limited to these specific exemplary embodiments. Additionally, while a typical “transparency” can have sufficient visible light transmission such that materials can be viewed through the transparency, the “transparency” need not be transparent to visible light but, may be translucent or opaque. That is, by “transparent” is meant having visible light transmission of greater than 0% up to 100%.

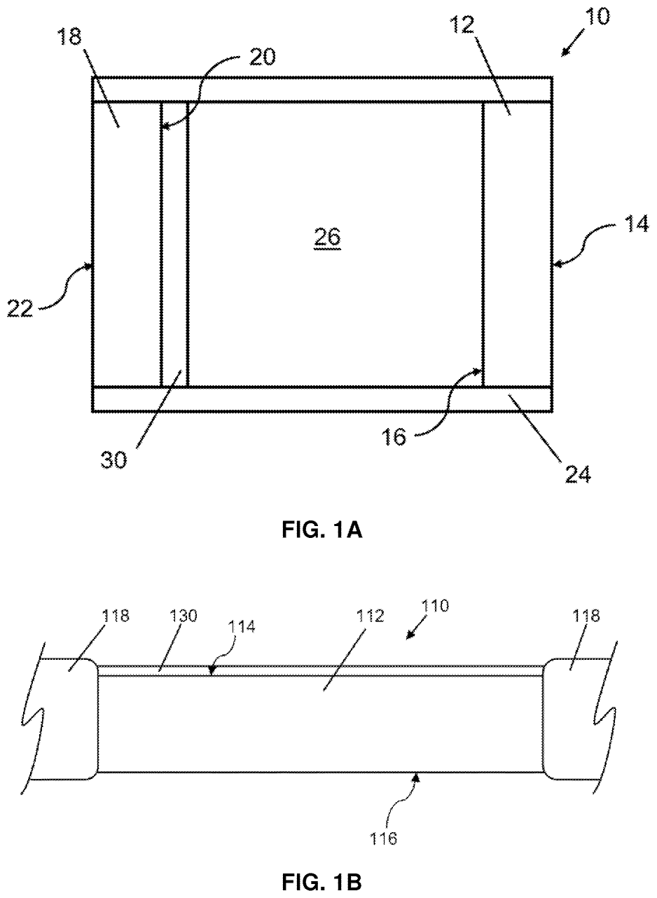

A non-limiting transparency 10 incorporating features of the invention is illustrated in FIG. 1A. The transparency 10 can have any desired visible light, infrared radiation, or ultraviolet radiation transmission and/or reflection.

The exemplary transparency 10 of FIG. 1A is in the form of a conventional insulating glass unit and includes a first ply 12 with a first major surface 14 (No. 1 surface) and an opposed second major surface 16 (No. 2 surface). In the illustrated non-limiting embodiment, the first major surface 14 faces the building exterior, i.e., is an outer major surface, and the second major surface 16 faces the interior of the building. The transparency 10 also includes a second ply 18 having an inner (first) major surface 20 (No. 3 surface) and an outer (second) major surface 22 (No. 4 surface) and spaced from the first ply 12. In some embodiments, the insulated glass unit includes a third ply with a first major surface (No. 5 surface) and an opposed second major surface (No. 6 surface). This numbering of the ply surfaces is in keeping with conventional practice in the fenestration art. The first and second plies 12, 18 can be connected in any suitable manner, such as, by being adhesively bonded to a conventional spacer frame 24. A gap or chamber 26 is formed between the two plies 12, 18. The chamber 26 can be filled with a selected atmosphere, such as, air, or a non-reactive gas such as, argon or krypton gas. A coating 30 (or any of the other coatings described below) is formed over at least a portion of the No. 3 surface 20 or at least a portion of the No. 4 surface 22 or at least a portion of the No. 5 surface or at least a portion of the No. 6 surface. The coating 30 is not over at least a portion of the No. 1 surface 14 or at least a portion of the No. 2 surface 16. Examples of insulating glass units are found, for example, in U.S. Pat. Nos. 4,193,228; 4,464,874; 5,088,258; and 5,106,663.

The exemplary transparency of FIG. 1B is in the form of a conventional transparency 110 for a vehicle, such as, a window or sunroof. For clarity, seals, connectors, and opening mechanisms are not shown, nor is the complete vehicle. The transparency includes a first ply 112 with a first major surface 114 (No. 1 surface) and an opposed second major surface 116 (No. 2 surface) mounted in the body of a vehicle 118 (shown in part). In the illustrated non-limiting embodiment, the first major surface 114 faces the vehicle's exterior, and thus is an outer major surface, and the second major surface 116 faces the interior of the vehicle. Non-limiting examples of a vehicle body include: an automobile roof in the case of a sunroof, an automobile door or frame in the case of an automobile window, or a fuselage of an airplane. The transparency may be affixed to a mechanism by which the transparency, such as, a car window or sunroof, can be opened and closes, as is broadly known in the vehicular arts. A coating 130, or any of the other coatings described herein, is shown as formed over the No. 1 surface 114, it may be formed over at least a portion of the No. 2 surface 116.

In the broad practice of the invention, the plies 12, 18, 112 of the transparency 10, 110 can be of the same or different materials. The plies 12, 18, 112 can include any desired material having any desired characteristics. For example, one or more of the plies 12, 18, 112 can be transparent or translucent to visible light. By “transparent” is meant having visible light transmission of greater than 0% up to 100%. Alternatively, one or more of the plies 12, 18, 112, can be translucent. By “translucent” is meant allowing electromagnetic energy (e.g., visible light) to pass through but diffusing this energy such that objects on the side opposite the viewer are not clearly visible. Examples of suitable materials include, but are not limited to, plastic substrates (such as acrylic polymers, such as, polyacrylates; polyalkylmethacrylates, such as polymethylmethacrylates, polyethylmethacrylates, polypropylmethacrylates, and the like; polyurethanes; polycarbonates; polyalkylterephthalates, such as, polyethyleneterephthalate (PET), polypropyleneterephthalates, polybutyleneterephthalates, and the like; polysiloxane-containing polymers; or copolymers of any monomers for preparing these, or any mixtures thereof); ceramic substrates; glass substrates; or mixtures or combinations of any of the above. For example, one or more of the plies 12, 18, 112 can include conventional soda-lime-silicate glass, borosilicate glass, or leaded glass. The glass can be clear glass. By “clear glass” is meant non-tinted or non-colored glass. Alternatively, the glass can be tinted or otherwise colored glass. The glass can be annealed or heat-treated glass. As used herein, the term “heat treated” means tempered or at least partially tempered. The glass can be of any type, such as, conventional float glass, and can be of any composition having any optical properties, e.g., any value of visible transmission, ultraviolet transmission, infrared transmission, and/or total solar energy transmission. By “float glass” is meant glass formed by a conventional float process in which molten glass is deposited onto a molten metal bath and controllably cooled to form a float glass ribbon. Examples of float glass processes are disclosed in U.S. Pat. Nos. 4,466,562 and 4,671,155.

The plies 12, 18, 112 can each comprise, for example, clear float glass or can be tinted or colored glass or one ply 12, 18 can be clear glass and the other ply 12, 18, colored glass. Although not limiting, examples of glass suitable for the first ply 12 and/or second ply 18 are described in U.S. Pat. Nos. 4,746,347; 4,792,536; 5,030,593; 5,030,594; 5,240,886; 5,385,872; and 5,393,593. The plies 12, 18, 112 can be of any desired dimensions, e.g., length, width, shape, or thickness. In one exemplary automotive transparency, the first and second plies can each be 1 mm to 10 mm thick, such as 1 mm to 8 mm thick, such as 2 mm to 8 mm, such as 3 mm to 7 mm, such as 5 mm to 7 mm, such as 6 mm thick.

In non-limiting embodiments of the coated articles described herein, the coating 30, 130 of the invention is deposited over at least a portion of at least one major surface of one of the glass plies 12, 18, 112. In the example according to FIG. 1A, the coating 30 is formed over at least a portion of the inner surface 20 of the inboard glass ply 18, 112; additionally or alternatively, it is to be understood that in non-limiting examples consistent with the present disclosure a solar control coating may be formed over at least a portion of the outer surface 22 of the inboard glass ply 18. As used herein, the term “solar control coating” refers to a coating comprised of one or more layers or films that affect the solar properties of the coated article, such as, but not limited to, the amount of solar radiation, for example, visible, infrared, or ultraviolet radiation, reflected from, absorbed by, or passing through the coated article; shading coefficient; emissivity, etc. The solar control coating 30 can block, absorb, or filter selected portions of the solar spectrum, such as, but not limited to, the IR, UV, and/or visible spectrums.

The coatings described herein, such as the solar control coatings 30, 130, can be deposited by any useful method, such as, but not limited to, conventional chemical vapor deposition (CVD) and/or physical vapor deposition (PVD) methods. Examples of CVD processes include spray pyrolysis. Examples of PVD processes include electron beam evaporation and vacuum sputtering (such as magnetron sputter vapor deposition (MSVD)). Other coating methods could also be used, such as, but not limited to, sol-gel deposition. In one non-limiting embodiment, the coating 30, 130 is deposited by MSVD. Examples of MSVD coating devices and methods will be well understood by one of ordinary skill in the art and are described, for example, in U.S. Pat. Nos. 4,379,040; 4,861,669; 4,898,789; 4,898,790; 4,900,633; 4,920,006; 4,938,857; 5,328,768; and 5,492,750.

The coated article comprises a substrate 210. Substrate 210 may include any desired properties, and be of any desired thickness. The substrate 210 may comprise any suitable transparent material or materials, such as, for example and without limitation, the polymers, glass, and/or ceramic substrates described above in the context of plies 12, 18, and 112. In non-limiting examples, substrate 210 may comprise a glass substrates as described above in reference to plies 12, 18, 112, as shown in FIG. 1A or 1B. However, it is to be understood that the present invention may be applied to other substrates as well, such as, those used in solar cells.

The functional coating 30, 130 may include a transparent conductive oxide (TCO), for example and without limitation, as disclosed in U.S. Patent Application Publication No 2019/0043640. The functional coating 30, 130 can include the stack as described in any of U.S. Patent Application Publication Nos. 2017/0341977, 2014/0272453, 2011/0228715, and/or U.S. patent application Ser. No. 15/669,414, or any portion thereof.

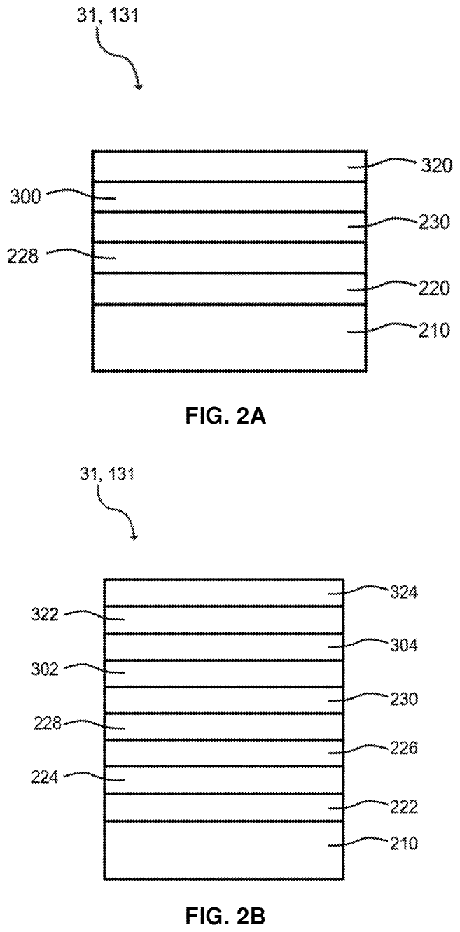

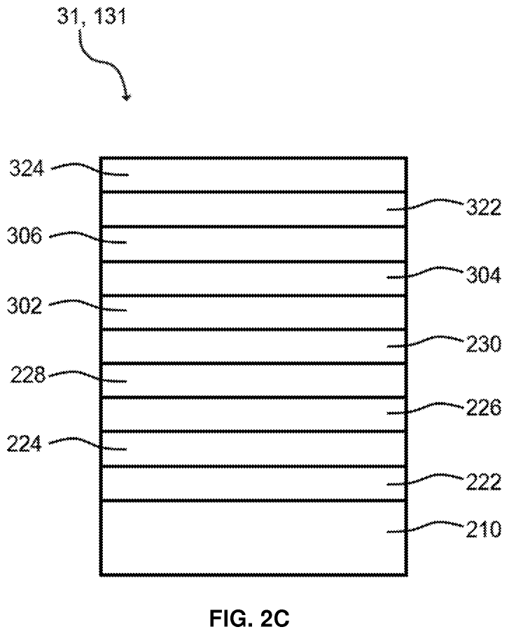

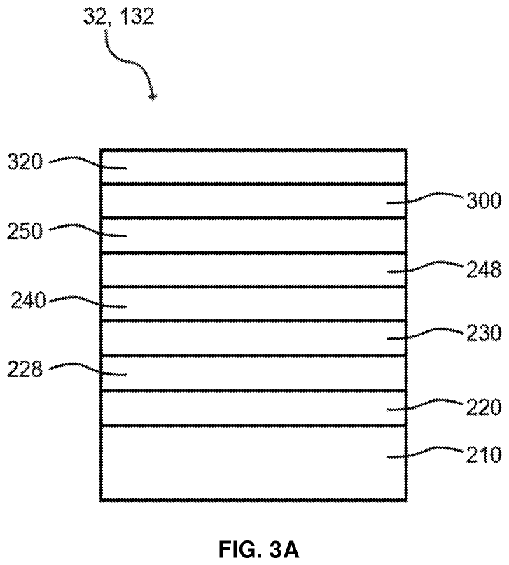

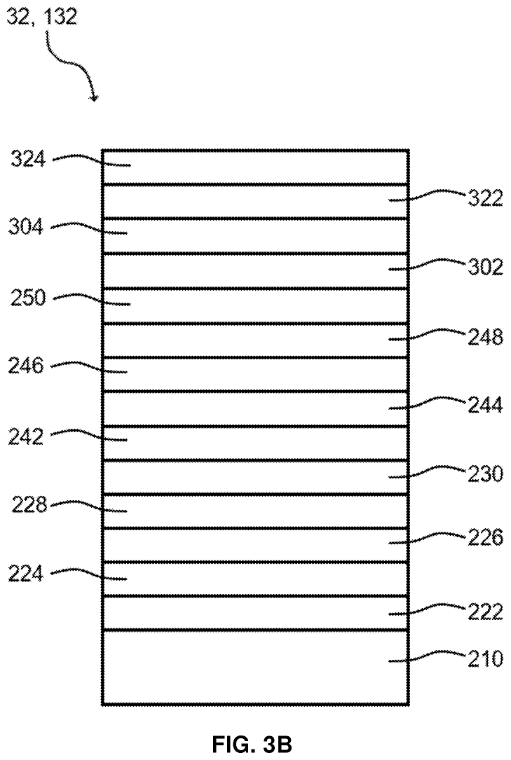

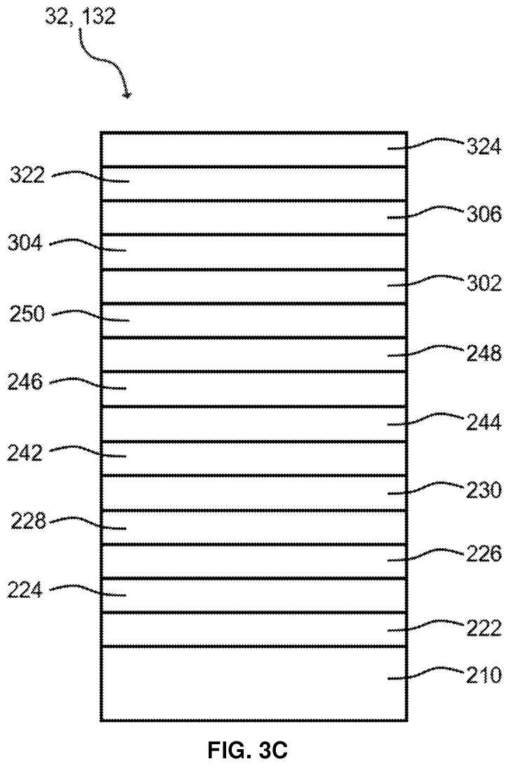

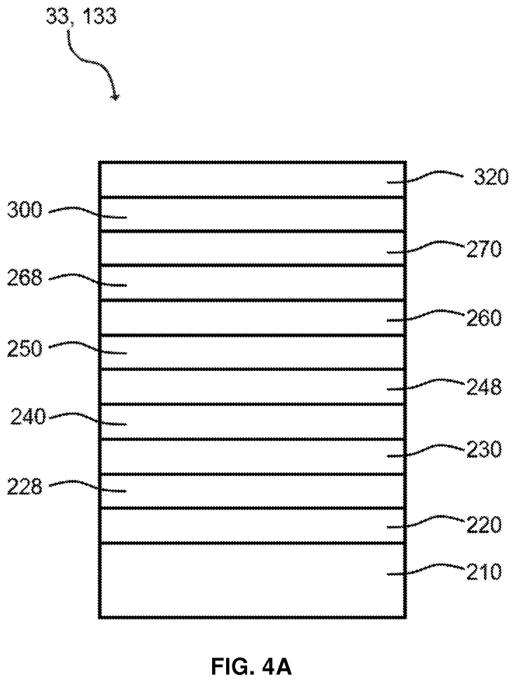

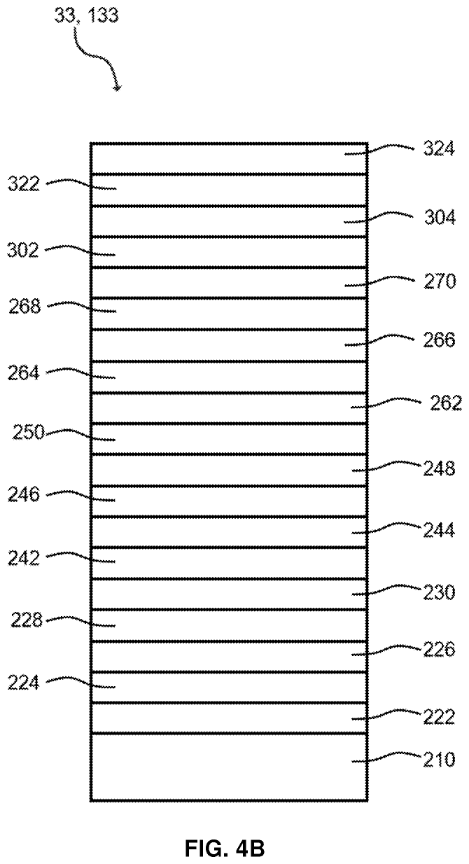

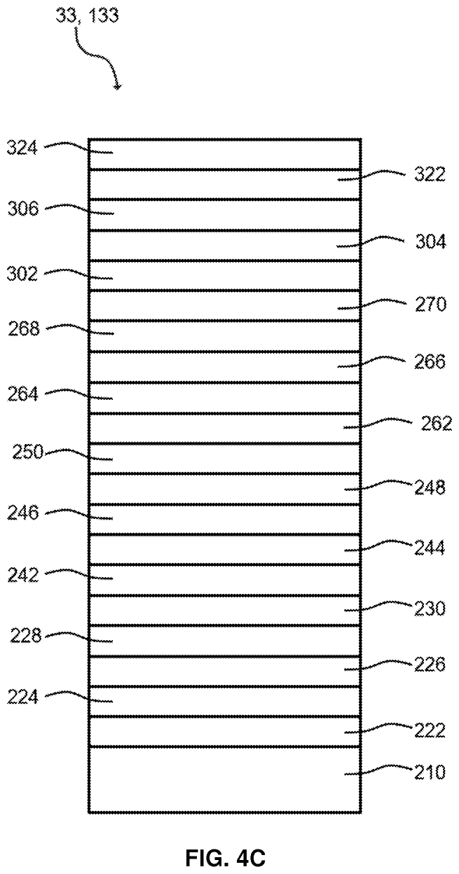

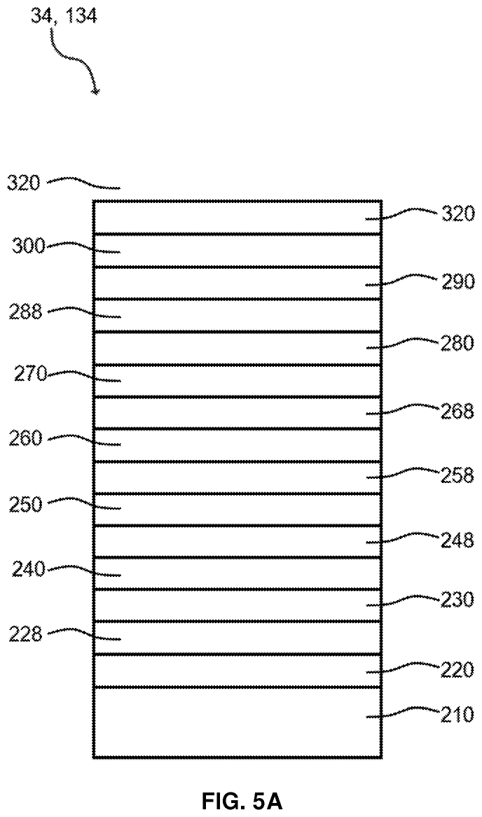

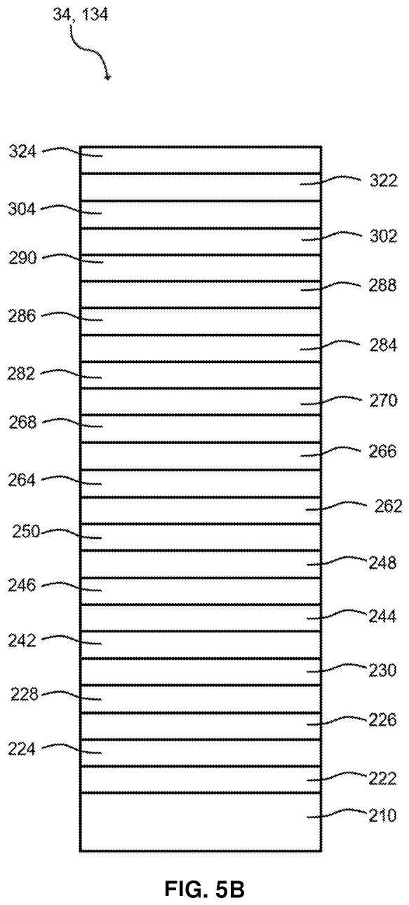

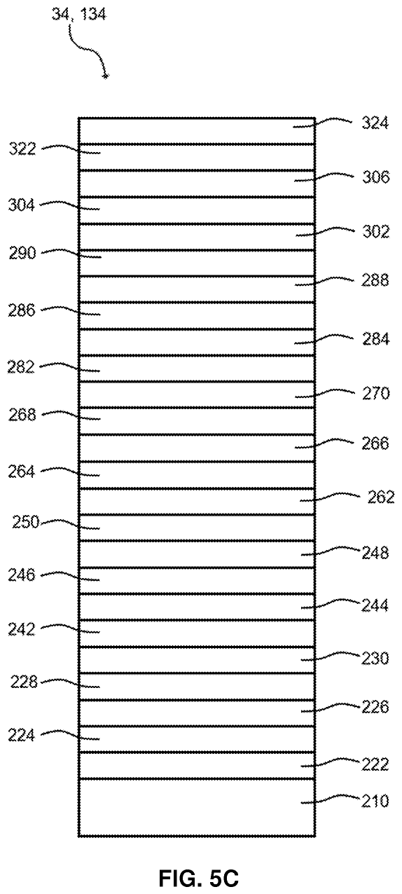

The coating 30, 130 can be a single metal coating 31, 131, e.g., one metallic layer, or a double metal coating 32, 132 (e.g., two metallic layers), or a triple metal coating 33, 133 (e.g., three metallic layers), or a quadruple metal coating 34, 134 (e.g., four metallic layers). Exemplary non-limiting coatings suitable for the single metal coating 31, 131 is shown in FIGS. 2A-2C. Exemplary non-limiting coatings suitable for the double metal coating 32, 132 is shown in FIGS. 3A-3C. Exemplary non-limiting coatings suitable for the triple metal coating 33, 133 is shown in FIGS. 4A-4C. Exemplary non-limiting coatings suitable for the quadruple metal coating 34, 134 is shown in FIGS. 5A-5C.

An exemplary coating 30, 130 includes one metallic layer (i.e., a single metal coating 31, 131), as shown in FIG. 2A. The single metal coating 31, 131 includes a blocking layer 220 positioned over or in direct contact with at least a portion of the substrate 210 (e.g., the No. 4 surface 22 of the second ply 18, or the No. 3 surface 20 of the second ply 18). A metallic layer 228 is positioned over or in direct contact with at least a portion of the blocking layer 220. An optional first primer layer 230 may be positioned over or in direct contact with at least a portion of the metallic layer 228. A top layer 300 is positioned over or in direct contact with at least a portion of the optional first primer layer 230 or the metallic layer 228. An optional outermost protective coating 320 may be positioned over or in direct contact with at least a portion of the top layer 300.

An exemplary coating 30, 130 includes two metallic layers (i.e., a double metal coating 32, 132), as shown in FIG. 3A. The double metal coating 32, 132 includes a blocking layer 220 positioned over or in direct contact with at least a portion of the substrate 210 (e.g., the No. 4 surface 22 of the second ply 18, or the No. 3 surface 20 of the second ply 18). A metallic layer 228 is positioned over or in direct contact with at least a portion of the blocking layer 220. An optional first primer layer 230 may be positioned over or in direct contact with at least a portion of the metallic layer 228. A first middle layer 240 is positioned over at least a portion of the optional first primer layer 230 or the metallic layer 228. A second metallic layer 248 is positioned over or in direct contact with at least a portion of the first middle layer 240. An optional second primer layer 250 is positioned over or in direct contact with at least a portion of the second metallic layer 248. A top layer 300 is positioned over or in direct contact with at least a portion of the optional second primer layer 250 or the second metallic layer 248. An optional outermost protective coating 320 may be positioned over or in direct contact with at least a portion of the top layer 300.

An exemplary coating 30, 130 includes three metallic layers (i.e., a triple metal coating 33, 133), as shown in FIG. 4A. The triple metal coating 33, 133 includes a blocking layer 220 positioned over or in direct contact with at least a portion of the substrate 210 (e.g., the No. 4 surface 22 of the second ply 18, or the No. 3 surface 20 of the second ply 18). A metallic layer 228 is positioned over or in direct contact with at least a portion of the blocking layer 220. An optional first primer layer 230 may be positioned over or in direct contact with at least a portion of the metallic layer 228. A first middle layer 240 is positioned over at least a portion of the optional first primer layer 230 or the metallic layer 228. A second metallic layer 248 is positioned over or in direct contact with at least a portion of the first middle layer 240. An optional second primer layer 250 is positioned over or in direct contact with at least a portion of the second metallic layer 248. A second middle layer 260 is positioned over or in direct contact with at least a portion of the optional second primer layer 250 or the second metallic layer 248. A third metallic layer 268 is positioned over or in direct contact with at least a portion of the second middle layer 260. An optional third primer layer 270 is positioned over or in direct contact with at least a portion of the third metallic layer 268. A top layer 300 is positioned over or in direct contact with at least a portion of the optional third primer layer 270 or the third metallic layer 268. An optional outermost protective coating 320 may be positioned over or in direct contact with at least a portion of the top layer 300.

An exemplary coating 30, 130 includes four metallic layers (i.e., a quadruple metal coating 34, 134), as shown in FIG. 5A. The quadruple metal coating 34, 134 includes a blocking layer 220 positioned over or in direct contact with at least a portion of the substrate 210 (e.g., the No. 4 surface 22 of the second ply 18, or the No. 3 surface 20 of the second ply 18). A metallic layer 228 is positioned over or in direct contact with at least a portion of the blocking layer 220. An optional first primer layer 230 may be positioned over or in direct contact with at least a portion of the metallic layer 228. A first middle layer 240 is positioned over at least a portion of the optional first primer layer 230 or the metallic layer 228. A second metallic layer 248 is positioned over or in direct contact with at least a portion of the first middle layer 240. An optional second primer layer 250 is positioned over or in direct contact with at least a portion of the second metallic layer 248. A second middle layer 260 is positioned over or in direct contact with at least a portion of the optional second primer layer 250 or the second metallic layer 248. A third metallic layer 268 is positioned over or in direct contact with at least a portion of the second middle layer 260. An optional third primer layer 270 is positioned over or in direct contact with at least a portion of the third metallic layer 268. A third middle layer 280 is positioned over or in direct contact with at least a portion of the optional third primer layer 270 or third metallic layer 268. A fourth metallic layer 288 is positioned over or in direct contact with at least a portion of the third middle layer 280. An optional fourth primer layer 290 is positioned over or in direct contact with at least a portion of the fourth metallic layer 288. A top layer 300 is positioned over or in direct contact with at least a portion of the optional fourth primer layer 290 or the fourth metallic layer 288. An optional outermost protective coating 320 may be positioned over or in direct contact with at least a portion of the top layer 300.

Exemplary non-limiting functional coatings 30, 130 of the invention is shown in FIGS. 2A-2C, 3A-3C, 4A-4C, and 5A-5C. This functional coating 30, 130 includes a blocking layer 220 deposited over at least a portion of a major surface of a substrate 210. The blocking layer 220 prevents the diffusion of zinc, sodium, calcium, magnesium, alkali metal elements, alkaline earth elements, or combinations thereof.

The functional coating 30, 130 comprises a blocking layer 220 over at least a portion of substrate. The blocking layer 220 can comprise more than one film of antireflective materials and/or dielectric materials, such as, but not limited to, metal oxides, oxides of metal alloys, nitrides, oxynitrides, or mixtures thereof. The blocking layer 220 can be transparent to visible light. Examples of suitable metal oxides for the blocking layer 220 include oxides of titanium, hafnium, zirconium, niobium, zinc, bismuth, lead, indium, tin, aluminum, silicon and mixtures thereof. These metal oxides can have small amounts of other materials, such as, manganese in bismuth oxide, tin in indium oxide, etc. Additionally, oxides of metal alloys or metal mixtures can be used, such as oxides containing zinc and tin (e.g., zinc stannate, defined below), oxides of indium-tin alloys, oxides containing zinc and aluminum, silicon nitrides, silicon aluminum nitrides, or aluminum nitrides. Further, doped metal oxides, such as, antimony or indium doped tin oxides or nickel or boron doped silicon oxides, can be used. The blocking layer 220 can be a substantially single phase film, such as, a metal alloy oxide film, e.g., zinc stannate, or can be a mixture of phases composed of zinc and tin oxides or can be composed of a plurality of films.

As shown in FIGS. 2B-2C, 3B-3C, 4B-4C, and 5B-5C, the blocking layer 220 may include a first film 222, a second film 224, and a third film 226, wherein the first film 222 is a blocking film. The blocking film 222 is over at least a portion of the substrate, a second film 224 is over at least a portion of the blocking film 222, and the third film 226 is over at least a portion of the second film 224.

In an exemplary embodiment, the blocking film 222 can comprise a metal oxide, a metal nitride, a metal oxynitride, or combinations thereof. In one non-limiting embodiment, the blocking film 222 comprises silicon oxide, silicon aluminum oxide, silicon nitride, silicon aluminum nitride, silicon oxynitride, silicon aluminum oxynitride, titanium oxide, titanium aluminum oxide, or combinations thereof. In another embodiment, the blocking film 222 comprises silicon oxide, silicon nitride, silicon aluminum nitride, silicon oxynitride, silicon aluminum oxynitride, titanium oxide, titanium aluminum oxide, or combinations thereof. In another embodiment, the blocking film 222 comprises silicon aluminum nitride. In another embodiment, the blocking film 222 comprises silicon aluminum oxynitride.

The blocking film 222 can be sputtered from two cathodes (e.g., one silicon and one aluminum) or from a single cathode containing both silicon and aluminum. The blocking film 222 can comprise from 5 wt. % to 20 wt. % aluminum and 95 wt. % to 80 wt. % silicon, such as 10 wt. % to 20 wt. % aluminum and 90 wt. % to 80 wt. % silicon, such as, 20 wt. % to 25 wt. % aluminum and 80 wt. % to 75 wt. % silicon. In one exemplary embodiment, the blocking film 222 comprises silicon and aluminum comprising 5 wt. % aluminum and 95 wt. % silicon. In another embodiment, the blocking film 222 comprises silicon and aluminum comprising 10 wt. % aluminum and 90 wt. % silicon. In another embodiment, the blocking film 222 comprises silicon and aluminum comprising 15 wt. % aluminum and 85 wt. % silicon. In another embodiment, the blocking film 222 comprises silicon and aluminum comprising 20 wt. % aluminum and 80 wt. % silicon. In another embodiment, the blocking film comprises silicon and aluminum comprising 25 wt. % aluminum and 75 wt. % silicon.

An oxide blocking film 222 is formed by sputtering the metal or metal alloy in an oxygen (O₂) atmosphere that has a specific flow rate to form an atmosphere of greater than 0% O₂ to less than or equal to 100% O₂. The flow rate is an approximation to the amount of O₂ in the atmosphere, but, that one of ordinary skill in the art would recognize that additional O₂ may leak into the coating chamber as the coating chamber is not hermetically sealed from the outside environment. For example, the O₂ flow rate (i.e., concentration of O₂ in the atmosphere for the chamber where the material is being deposited) can be in the range of 0% to 50%, such as, 10% to 50%, such as, 20% to 30%, such as, 20% to 40%, such as, 20% to 50%, such as, 30% to 40%, such as, 30% to 50%. The remainder of the atmosphere can be an inert gas, such as, argon.

A nitride blocking layer 222 is formed by sputtering the metal or metal alloy in a nitrogen (N₂) atmosphere that has a specific flow rate as to form an atmosphere of greater than 0% N₂ to less than or equal to 100% N₂. The flow rate is an approximation to the amount of N₂ in the atmosphere, but that one of ordinary skill in the art would recognize that additional N₂ may leak into the coating chamber as the coating chamber is not hermetically sealed from the outside environment. For example, the N₂ flow rate (i.e. concentration of N₂ in the atmosphere for the chamber where the material is being deposited) can be in the range of 0% to 80%, such as, 1% to 40%, such as, 3% to 35%, such as, 5% to 30%, such as, 5% to 80%. The remainder of the atmosphere can be an inert gas, such as argon.

An oxynitride blocking layer 222 can be formed by sputtering the metal or metal alloy in an O₂ and N₂ environment. For example, the N₂ flow rate (i.e., concentration of N₂ in the atmosphere for the chamber where the material is being deposited) can be 50 to 100% and the O₂ flow rate (i.e., the concentration of O₂ in the atmosphere for the chamber where the material is being deposited) can be 0% to 50%. The N₂ flow rate can be from 95% to 50% and the O₂ flow rate can be 5% to 50%, such as 90% to 50% N₂ and 10% to 50% O₂, such as, 80% to 50% N₂ and 20% to 50% O₂, such as, 70% to 50% N₂ and 30% to 50% O₂. In one embodiment, the N₂ flow rate can be 90% and the O₂ flow rate can be 10%. In one embodiment, the N₂ flow rate can be 80% and the O₂ flow rate can be 20%. In one embodiment, the N₂ flow rate can be 70% and the O₂ flow rate can be 30%. In one embodiment, the N₂ flow rate can be 60% and the O₂ flow rate can be 40%. In one embodiment, the N₂ flow rate can be 50% and the O₂ flow rate can be 50%.

The atomic ratio of oxygen and nitrogen in metal oxynitrides is an approximation based on the flow rate of N₂ and the flow rate of 02. The atomic ratio of oxygen and nitrogen in metal oxynitrides can vary, from 0 wt. % to 100 wt. %, where wt. % refers to the ratio of the mass of N or O to the total mass of N+O in the composition, excluding the metals of the metal oxynitride. The metal oxynitride blocking film 222 comprises 0 wt. % oxygen, and not more than 50 wt. % oxygen; not more than 40 wt. % oxygen; not more than 30 wt. % oxygen; not more than 20 wt. % oxygen; not more than 10 wt. % oxygen; not more than 5 wt. % oxygen. Non-limiting examples of useful atomic ratios of oxygen and nitrogen in the metal oxynitride film include, for example and without limitation from 5% to 50% O with from 95% to 50% N; from 10 to 50% O with from 90% to 50% N; from 15% to 40% O to 85% to 60% N; from 20% to 50% O to 80% to 50% N; from 25% to 45% O to 75% to 55% N; from 30% to 50% O to 70% to 50% N; from 40% to 50% O to 60% to 50% N; or 50% O with 50% N.

The blocking film 222, such as, a film comprised of silicon aluminum oxynitride, according to the present disclosure may have an index of refraction, at 550 nm, of at least 1.4, and not more than 2.3. In one embodiment, the blocking film 222 has an index of refraction of at least 1.45, and not more than 2.2. In another embodiment, the blocking film 222 has an index of refraction of 1.70 to 1.80, for example, 1.75. It is to be understood that the index of refraction of the blocking film 222 at least partially depends on the weight percentage of nitrogen present in the blocking film.

The blocking film 222 can comprise a total thickness of 50 Å to 350 Å, preferably 50 Å to 300 Å, or most preferably 100 Å to 250 Å.

In one non-limiting embodiment, the second film 224 of the blocking layer 220 comprises zinc stannate. By “zinc stannate” is meant a composition of ZnₓSn₁₋ₓO₂₋ₓ (Formula 1) where “x” varies in the range of greater than 0 to less than 1. For instance, “x” can be greater than 0 and can be any fraction or decimal between greater than 0 to less than 1. For example, where x=2/3, Formula 1 is Zn_{2/3}Sn_{1/3}O_{4/3}, which is more commonly described as “Zn₂SnO₄”. A zinc stannate-containing film has one or more of the forms of Formula 1 in a predominant amount in the layer.

In one non-limiting embodiment, the third film 226 of the blocking layer 220 can be a zinc/tin alloy oxide. By “zinc/tin alloy oxide” is meant both true alloys, and mixtures of the oxides. Zinc oxide can be deposited from a zinc cathode that includes other materials to improve the sputtering characteristics of the cathode. As such, the zinc/tin alloy oxide can be obtained from magnetron sputtering vacuum deposition from a cathode of zinc and tin. For example, the zinc cathode can include a small amount (e.g., up to 20 wt. %, up to 15 wt. %, up to 10 wt. %, or up to 5 wt. %) of tin to improve sputtering. In which case, the resultant zinc oxide film would include a small percentage of tin oxide, e.g., up to 10 wt. % tin oxide, e.g., up to 5 wt. % tin oxide. A coating layer deposited from a zinc cathode having up to 10 wt. % tin (added to enhance the conductivity of the cathode) is referred to herein as “a zinc oxide film” even though a small amount of tin may be present. One non-limiting cathode can comprise zinc and tin in proportions of from 5 wt. % to 95 wt. % zinc and from 95 wt. % to 5 wt. % tin, such as from 10 wt. % to 90 wt. % zinc and from 90 wt. % to 10 wt. % tin. However, other ratios of zinc to tin could also be used.

In one non-limiting embodiment, the third film 226 of the blocking layer 220 can be an aluminum/zinc alloy oxide (AlₓZn₁₋ₓ oxide). By “aluminum/zinc alloy oxide” is meant both true alloys, and mixtures of the oxides. As such, the aluminum/zinc alloy oxide can be obtained from magnetron sputtering vacuum deposition from a cathode of zinc and aluminum and can include a small of amount (e.g. less than 10 wt. %, such as, greater than 0 to 5 wt. %) of tin to improve sputtering. In which case, the resultant aluminum zinc oxide film would include a small percentage of tin oxide, e.g. 0 wt. % to less than 10 wt. %, e.g., 0 wt. % to 5 wt. % tin oxide. The third film 226 of the blocking layer 220 can comprise AlₓZn₁₋ₓ oxide, where x is within the range of 1 wt. % to 25 wt. %, preferably 1 wt. % to 15 wt. %, more preferably 1 wt. % to 10 wt. %, and most preferably 2 wt. % to 5 wt. %. In one non-limiting embodiment, x is 3 wt. %.

In one non-limiting embodiment, the blocking film 222 of the blocking layer 220 comprises silicon aluminum oxynitride over at least a portion of the substrate, the second film 224 of the blocking layer 220 comprises zinc stannate over at least a portion of the blocking film 222, and the third film 226 of the blocking layer 220 comprises zinc oxide or aluminum zinc oxide over at least a portion of the second film 224. The second film 224 can comprise zinc stannate having a thickness in the range of 50 Å to 400 Å, preferably 80 Å to 300 Å, or most preferably 90 Å to 250 Å. The third film 226 can comprise zinc oxide or aluminum zinc oxide having a thickness in the range of 50 Å to 100 Å, preferably 50 Å to 90 Å, most preferably 60 Å to 90 Å.

The blocking layer 220 comprises a total thickness (e.g., combined thickness of the first, second, and third films 222, 224, 226) of 150 Å to 850 Å, preferably 250 Å to 600 Å, or most preferably 200 Å to 500 Å.

A metallic layer 228 can be deposited over at least a portion of the blocking layer 220. The metallic layer 228 can include a reflective metal, such as, but not limited to, metallic gold, copper, palladium, aluminum, silver, or mixtures, alloys, or combinations thereof. In one embodiment, the metallic layer 228 comprises a metallic silver layer. The metallic layer 228 is a continuous layer. By “continuous layer” is meant that the coating forms a continuous film of the material and not isolated coating regions.

The first metallic layer 228 can have a thickness in the range of 60 Å to 150 Å, such as 60 Å to 100 Å, such as, 60 Å to 90 Å.

A first primer layer 230 is located over the metallic layer 228. The first primer layer 230 can be a single film or a multiple film layer. The first primer layer 230 can include an oxygen-capturing material that can be sacrificial during the deposition process to prevent degradation or oxidation of the metallic layer 228 during the sputtering process or subsequent heating processes. The first primer layer 230 can also absorb at least a portion of electromagnetic radiation, such as, visible light, passing through the functional coating 30, 130. Examples of materials useful for the first primer layer 230 include titanium, silicon, silicon dioxide, silicon nitride, silicon oxynitride, nickel, zirconium, zinc, aluminum, cobalt, chromium, an alloy thereof, or a mixture thereof. In one non-limiting embodiment, the first primer layer 230 comprises titanium, titanium and aluminum, or zinc and aluminum, which are deposited as a metal and at least a portion of the titanium, or titanium and aluminum, or zinc and aluminum are subsequently oxidized. In another embodiment, the primer layer 230 comprises a nickel-chromium alloy, such as, Inconel. In another embodiment, the primer layer 230 comprises a cobalt-chromium alloy, such as, Stellite®.

The first primer layer 230 can have a thickness in the range of 5 Å to 50 Å, preferably 10 Å to 35 Å, or more preferably 10 Å to 30 Å.

A first middle layer 240 is located over at least a portion of the metallic layer 228 (e.g., over the first primer layer 230). The first middle layer 240 can comprise one or more metal oxide or metal alloy oxide-containing films, such as, those described above with respect to the blocking layer 220. For example, the first middle layer 240 can include a first film 242 comprising a metal oxide, e.g., a zinc oxide or aluminum zinc oxide, deposited over at least a portion of the first primer layer 230, a second film 244 comprising a metal oxide, e.g., a zinc stannate film over at least a portion of the first film 242, and a third film 246 comprising a metal oxide, e.g., a zinc oxide film or aluminum zinc oxide film, over at least a portion of the second film 244.

In one example, both of the first and third films 242, 246 are present and each has a thicknesses in the range of 10 Å to 200 Å, e.g., 50 Å to 200 Å, e.g., 60 Å to 150 Å, e.g., 70 Å to 85 Å. The second film 244 can have a thickness in the range of 50 Å to 800 Å, e.g., 50 Å to 500 Å, e.g., 100 Å to 300 Å, e.g., 110 Å to 235 Å, e.g., 110 Å to 120 Å.

The first middle layer 240 can comprise a total thickness (e.g., the combined thicknesses of the films) in the range of 50 Å to 1000 Å, such as 50 Å to 500 Å, such as, 100 Å to 370 Å, such as, 100 Å to 300 Å, such as, 100 Å to 200 Å, such as, 150 Å to 200 Å, such as, 180 Å to 190 Å.

A second metallic layer 248 can be formed over a least a portion of the first middle layer. The second metallic layer 248 can include a reflective metal, such as, but not limited to, metallic gold, copper, palladium, aluminum, silver, or mixtures, alloys, or combinations thereof. In one embodiment, the second metallic layer 248 comprises a metallic silver layer.

In one embodiment, the second metallic layer 248 is a continuous layer formed over at least a portion of the first middle layer 240. The second metallic layer 248 is a continuous layer having a total thickness of 50 Å to 300 Å, such as 100 Å to 200 Å, such as, 150 Å to 200 Å, such as, 170 Å to 200 Å, such as, 60 Å to 150 Å, such as, 60 Å to 100 Å, such as, 60 Å to 90 Å.

In another embodiment, the second metallic layer 248 is a discontinuous layer, having a subcritical thickness, formed over at least a portion of the first middle layer 240. The metallic material, such as, but not limited to, metallic gold, copper, palladium, aluminum, silver, or mixtures, alloys, or combinations thereof, is applied at a subcritical thickness such that isolated regions or islands of the material are formed rather than a continuous layer of the material. For silver, it has been determined that the critical thickness is less than 50 Å, such as, less than 40 Å, such as less than 30 Å, such as, less than 25 Å. For silver, the transition between a continuous layer and a subcritical layer occurs in the range of 25 Å to 50 Å. For copper, it has been determined that the effective thickness is at most 90 Å; e.g., 50 Å; 40 Å; e.g., 36 Å, e.g., 26 Å; e.g., 20 Å; e.g., 17 Å; and at least 1 Å; e.g., 2 Å; e.g. 3 Å; e.g. 4 Å; e.g. 5 Å; e.g. 6 Å; e.g. 7 Å. It is estimated that copper, gold, and palladium would exhibit similar subcritical behavior in this range. In one non-limiting embodiment, the second metallic layer 248 comprises islanded silver with the islands having an effective thickness of at most 70 Å, e.g. at most 40 Å, e.g., at most 35 Å, e.g., at most 30 Å, e.g., at most 25 Å, e.g., at most 20 Å; e.g., at most 17 Å; and at least 1 Å; e.g., at least 2 Å; e.g., at least 4 Å; e.g., at least 5 Å; e.g. at least 7 Å; e.g., at least 10 Å. In another embodiment, the second metallic layer 248 comprises copper with the islands having an effective thickness is at most 90 Å; e.g., 50 Å; 40 Å; e.g., 36 Å, e.g., 26 Å; e.g., 20 Å; e.g., 17 Å; and at least 1 Å; e.g., 2 Å; e.g. 3 Å; e.g. 4 Å; e.g. 5 Å; e.g. 6 Å; e.g. 7 Å; and optionally silver with islands having an effective thickness of at most 70 Å, e.g. at most 40 Å, e.g., at most 35 Å, e.g., at most 30 Å, e.g., at most 25 Å, e.g., at most 20 Å; e.g., at most 17 Å; and at least 1 Å; e.g., at least 2 Å; e.g., at least 4 Å; e.g., at least 5 Å; e.g. at least 7 Å; e.g., at least 10 Å. The second metallic layer 248 absorbs electromagnetic radiation according to the Plasmon Resonance Theory. This absorption depends at least partly on the boundary conditions at the interface of the metallic islands. The second metallic layer 248 is not an infrared reflecting layer, like the metallic layer 248. It is estimated that for silver and copper, the metallic islands or balls of silver metal and copper metal deposited below the subcritical thickness can have a height of about 20 Å to 70 Å, such as 50 Å to 70 Å. It is estimated that if the subcritical metal layer could be spread out uniformly, it would have a thickness of about 11 Å. It is estimated that optically, the discontinuous metal layer behaves as an effective layer thickness of 26 Å. Depositing the discontinuous metallic layer over zinc stannate rather than zinc oxide or aluminum zinc oxide appears to increase the visible light absorbance of the coating, e.g., of the discontinuous metallic layer.

A second primer layer 250 is located over the second metallic layer 248. The second primer layer 250 can be a single film or a multiple film layer. The second primer layer 250 can be any of the materials used for the first primer 230. The second primer layer 250 can have a thickness in the range of 5 Å to 50 Å, preferably 10 Å to 35 Å, or more preferably 10 Å to 30 Å.

A second middle layer 260 is located over at least a portion of the second metallic layer 248 (e.g., over the second primer layer 250). The second middle layer 260 can comprise one or more metal oxide or metal alloy oxide-containing films, such as, those described above with respect to the blocking layer 220. For example, the second middle layer 260 can include a first film 262 comprising a metal oxide, e.g., a zinc oxide or an aluminum zinc oxide, deposited over at least a portion of the second primer layer 250, a second film 264 comprising a metal oxide, e.g., a zinc stannate film over at least a portion of the first film 262, and a third film 266 comprising a metal oxide, e.g., a zinc oxide film or an aluminum zinc oxide film, over at least a portion of the second film 264.

The second middle layer 260 comprises a total thickness (e.g., the combined thicknesses of the layers) in the range of 200 Å to 1000 Å, such as 400 Å to 900 Å, such as, 500 Å to 900 Å, such as, 650 Å to 800 Å, such as, 690 Å to 720 Å.

In one example, both of the first and third films 262, 266 are present and each has a thicknesses in the range of 50 Å to 200 Å, such as, 75 Å to 150 Å, such as, 80 Å to 150 Å, such as, 95 Å to 100 Å. The second film 264 can have a thickness in the range of 100 Å to 800 Å, e.g., 200 Å to 700 Å, e.g., 300 Å to 600 Å, e.g., 380 Å to 500 Å, e.g., 380 Å to 450 Å.

A third metallic layer 268 can be formed over a least a portion of the second middle layer 260. The third metallic layer 268 can include a reflective metal, such as, but not limited to, metallic gold, copper, palladium, aluminum, silver, or mixtures, alloys, or combinations thereof. In one embodiment, the second metallic layer 268 comprises a metallic silver layer.

In one embodiment, the third metallic layer 268 is a continuous layer formed over at least a portion of the second middle layer. The third metallic layer 268 is a continuous layer having a total thickness of 25 Å to 300 Å, such as, 50 Å to 300 Å, such as, 50 Å to 200 Å, such as, 70 Å to 200 Å, such as, 100 Å to 200 Å, such as, 170 Å to 200 Å, such as, 60 Å to 150 Å, such as, 60 Å to 100 Å, such as, 60 Å to 90 Å.

In another embodiment, the third metallic layer 268 is a discontinuous layer, having a subcritical thickness, formed over at least a portion of the second middle layer. The metallic material, such as, but not limited to, metallic gold, copper, palladium, aluminum, silver, or mixtures, alloys, or combinations thereof, is applied at a subcritical thickness such that isolated regions or islands of the material are formed rather than a continuous layer of the material. For silver, it has been determined that the critical thickness is less than 50 Å, such as less than 40 Å, such as less than 30 Å, such as less than 25 Å. For silver, the transition between a continuous layer and a subcritical layer occurs in the range of 25 Å to 50 Å. For copper, it has been determined that the effective thickness is at most 90 Å; e.g., 50 Å; 40 Å; e.g., 36 Å, e.g., 26 Å; e.g., 20 Å; e.g., 17 Å; and at least 1 Å; e.g., 2 Å; e.g. 3 Å; e.g. 4 Å; e.g. 5 Å; e.g. 6 Å; e.g. 7 Å. It is estimated that copper, gold, and palladium would exhibit similar subcritical behavior in this range. In one non-limiting embodiment, the third metallic layer 268 comprises islanded silver with the islands having an effective thickness of at most 70 Å, e.g. at most 40 Å, e.g., at most 35 Å, e.g., at most 30 Å, e.g., at most 25 Å, e.g., at most 20 Å; e.g., at most 17 Å; and at least 1 Å; e.g., at least 2 Å; e.g., at least 4 Å; e.g., at least 5 Å; e.g. at least 7 Å; e.g., at least 10 Å. In another embodiment, the third metallic layer 268 comprises copper with the islands having an effective thickness is at most 90 Å; e.g., 50 Å; 40 Å; e.g., 36 Å, e.g., 26 Å; e.g., 20 Å; e.g., 17 Å; and at least 1 Å; e.g., 2 Å; e.g. 3 Å; e.g. 4 Å; e.g. 5 Å; e.g. 6 Å; e.g. 7 Å; and optionally silver with islands having an effective thickness of at most 70 Å, e.g. at most 40 Å, e.g., at most 35 Å, e.g., at most 30 Å, e.g., at most 25 Å, e.g., at most 20 Å; e.g., at most 17 Å; and at least 1 Å; e.g., at least 2 Å; e.g., at least 4 Å; e.g., at least 5 Å; e.g. at least 7 Å; e.g., at least 10 Å. The third metallic layer 268 absorbs electromagnetic radiation according to the Plasmon Resonance Theory. This absorption depends at least partly on the boundary conditions at the interface of the metallic islands.

The third metallic layer 268 is not an infrared reflecting layer, like the metallic layer 228. It is estimated that for silver and copper, the metallic islands or balls of silver metal and copper metal deposited below the subcritical thickness can have a height of about 20 Å to 70 Å, such as, 50 Å to 70 Å. It is estimated that if the subcritical metal layer could be spread out uniformly, it would have a thickness of about 11 Å. It is estimated that optically, the discontinuous metal layer behaves as an effective layer thickness of 26 Å.

A third primer layer 270 is located over the third metallic layer 268. The third primer layer 270 can be a single film or a multiple film layer. The third primer layer 270 can be any of the materials used for the first primer layer 230.

The third primer layer 270 can have a thickness in the range of 5 Å to 50 Å, preferably 10 nm to 35 Å, or more preferably 10 Å to 30 Å.

A third middle layer 280 is located over at least a portion of the third metallic layer 268 (e.g., over the third primer layer). The third middle layer 280 can comprise one or more metal oxide or metal alloy oxide-containing films, such as, those described above with respect to the blocking layer 220 For example, the third middle layer can include a first film 282 comprising a metal oxide, e.g., a zinc oxide or an aluminum zinc oxide, deposited over at least a portion of the third primer layer 270, a second film 284 comprising a metal oxide, e.g., a zinc stannate film over at least a portion of the first film 282, and a third film 286 comprising a metal oxide, e.g., a zinc oxide film or an aluminum zinc oxide film, over at least a portion of the second film 284.

The third middle layer 280 comprises a total thickness (e.g., the combined thicknesses of the layers) in the range of 200 Å to 1000 Å, such as 400 Å to 900 Å, such as, 500 Å to 900 Å, such as, 650 Å to 800 Å, such as, 690 Å to 720 Å.

In one example, both of the first and third films 282, 286 are present and each has a thicknesses in the range of 50 Å to 200 Å, such as, 75 Å to 150 Å, such as 80 Å to 150 Å, such as 95 Å to 100 Å. The second film 284 can have a thickness in the range of 100 Å to 800 Å, e.g., 200 Å to 700 Å, e.g., 300 Å to 600 Å, e.g., 380 Å to 500 Å, e.g., 380 Å to 450 Å.

A fourth metallic layer 288 formed over a least a portion of the third middle layer 280. The fourth metallic layer 288 can include a reflective metal, such as, but not limited to, metallic gold, copper, palladium, aluminum, silver, or mixtures, alloys, or combinations thereof. The fourth metallic layer 288 is a continuous layer. In some embodiments, the fourth metallic layer 288 comprises a metallic silver layer.

The fourth metallic layer 288 is a continuous layer having a total thickness of 60 Å to 150 Å, preferably 60 Å to 100 Å, or most preferably 60 Å to 90 Å.

A fourth primer layer 290 is located over the fourth metallic layer 288. The third primer layer 290 can be a single film or a multiple film layer. The fourth primer layer 290 can be any of the materials used for the first primer layer 230. The fourth primer layer 290 can have a thickness in the range of 5 Å to 50 Å, preferably 10 Å to 35 Å, or more preferably 10 Å to 30 Å.

A top layer 300 is located over the uppermost metallic layer (e.g., over the uppermost primer layer). In a single metallic layer functional coating 31, 131, the top layer 300 is formed over at least a portion of the metallic layer 228 (e.g., over the first primer layer 230). In a double metallic layer functional coating 32, 132, the top layer 300 is formed over at least a portion of the second metallic layer 248 (e.g., over the second primer layer 250). In a triple metallic layer functional coating 33, 133, the top layer 300 is formed over at least a portion of the third metallic layer 268 (e.g., over the third primer layer 270). In a quadruple metallic layer functional coating 34, 134 the top layer 300 is formed over at least a portion of the fourth metallic layer 288 (e.g., over at least a portion of the fourth primer layer 290).

The top layer 300 can comprise one or more metal oxide or metal alloy oxide-containing films, such as, those described above with respect to the blocking layer 220. For example, the top layer 300 can include a first metal oxide film 302, e.g., a zinc stannate film, deposited over the uppermost metallic layer (e.g., uppermost primer layer) and a second metal oxynitride film 304, e.g., a silicon aluminum oxynitride, deposited over at least a portion of the first metal oxide film 302 (FIGS. 2B, 3B, 4B, and 5B). In another embodiment, the top layer 300 can include a first metal oxide film 302, e.g., a zinc oxide film or an aluminum zinc oxide film, deposited over the uppermost metallic layer (e.g., uppermost primer layer), a second metal alloy film 304, e.g., a zinc stannate film, deposited over at least a portion of the first film 302, and a third metal alloy oxynitride film 306, e.g., a silicon aluminum oxynitride film, deposited over the second zinc stannate film 304 (FIGS. 2C, 3C, 4C, and 5C).

The top layer 300 can have a total thickness (e.g., the combined thicknesses of the layers) in the range of 50 Å to 750 Å, preferably 250 Å to 600 Å, more preferably 300 Å to 550 Å, or most preferably 300 Å to 400 Å.

An optional outermost protective coating 320 is formed over at least a portion of the top layer 300 and is the uppermost layer of the coated article. The outermost protective coating 320 can help protect the underlying functional coating layers, from mechanical and/or chemical attack. The outermost protective coating 320 can be an oxygen barrier coating layer to prevent or reduce the passage of ambient oxygen into the underlying layers of the coating, such as during heating or bending. The outermost protective coating 320 can be of any desired material or mixture of materials and can be comprised of one or more protective films. The outermost protective coating 320 comprises a protective layer, wherein the protective layer comprises at least one of Si₃N₄, SiAlN, SiAlON, TiAlO, titania, alumina, silica, zirconia, or combinations thereof.

In one embodiment, the outermost protective layer may be comprised of a first protective film 322 and second protective film 324 over at least a portion of the first protective film 322. In one embodiment, the first protective film 322 comprises a metal nitride film, e.g., a silicon aluminum nitride, disposed over and in contact with metal oxynitride film (e.g., silicon aluminum oxynitride) of the top layer 300 and the second protective film 324 comprises a metal alloy oxide, such as titanium aluminum oxide, disposed over and in contact with the first protective film 322.

In one embodiment, the metal oxynitride film of the top layer 300 is a metal oxynitride of the same metal as in the first protective metal nitride film 322 that contacts the metal oxynitride film of the top layer 300. In another embodiment, the metal oxynitride film of the top layer 300 is a gradient layer wherein the portion of the metal oxynitride film that is closest to the uppermost metal alloy film of the top layer 300 comprises a greater amount of oxygen, and the opposite portion of the metal oxynitride film, e.g., that is closest to the first protective metal nitride film 322, comprises a greater amount of nitrogen, for example, in atomic ratios described above. In one embodiment, the metal oxynitride film of the top layer 300 and the first protective metal nitride film 322 form a continuous, single gradient layer. In another embodiment, the metal oxynitride film of the top layer 300 is applied over a metal alloy oxide film and/or in between a metal alloy oxide film and the first protective metal nitride film 322. In another embodiment, the first protective metal nitride film 322 is not present, and the metal oxynitride film of the top layer 300 is a gradient layer, wherein amount of oxygen in the metal oxynitride film of the top layer 300 decreases with increased distance from the metal alloy oxide film of top layer 300. For example, the portion of the metal oxynitride film of the top layer 300 that is closest to the uppermost metal alloy oxide film of the top layer 300 comprises a greater amount of oxygen, and the opposite portion of the oxynitride film of the top layer 300, comprises a greater amount of nitrogen, where the atomic ratio of oxygen and nitrogen in metal oxynitrides is an approximation based on the flow rate of N₂ and the flow rate of 02. The oxynitride film of the top layer 300 comprises 0 wt. % oxygen, and not more than 50 wt. % oxygen; not more than 40 wt. % oxygen; not more than 30 wt. % oxygen; not more than 20 wt. % oxygen; not more than 10 wt. % oxygen; not more than 5 wt. % oxygen. Non-limiting examples of useful atomic ratios of oxygen and nitrogen in the oxynitride film of the top layer 300 include, for example, and without limitation, from 5% to 45% O with from 95% to 55% N; from 10 to 50% O with from 90% to 50% N; from 15% to 40% O to 85% to 60% N; from 20% to 50% O to 80% to 50% N; from 25% to 45% O to 75% to 55% N; from 30% to 50% O to 70% to 50% N; from 40% to 50% O to 60% to 50% N; or 50% O with 50% N.

The metal oxynitride film of the top layer 300 can have a thickness in the range of from >0 Å to 400 Å, such as, from 70 Å to 400 Å, from 100 Å to 400 Å, from 280 Å to 330 Å, or from 120 Å to 220 Å. In embodiments where the metal oxynitride film of the top layer 300 is a gradient layer, or where there is no metal nitride film in the outermost protective coating, it may have a thickness of 200 Å to 400 Å, preferably 225 Å to 390 Å, more preferably 250 Å to 380 Å, most preferably 280 Å to 375 Å.

The first protective metal nitride film 322 can have a thickness in the range of from >0 Å to 400 Å, such as from 70 Å to 400 Å, from 100 Å to 400 Å, from 250 Å 400 Å, from 280 Å to 330 Å, from 200 Å to 250 Å, from 200 Å to 400 Å, or from 100 Å to 160 Å. In embodiments where there is no metal oxynitride film of the top layer 300 and/or no second protective film, the first protective metal nitride film 322 can have a thickness in the range of 100 Å to 400 Å, preferably 250 Å to 400 Å, most preferably 280 Å to 330 Å. In embodiments where the top layer 300 has a metal oxynitride film and the outermost protective coating 320 has a second protective film 324, the first protective metal nitride film 322 can have a thickness of 100 Å to 400 Å, preferably 100 Å to 330 Å, more preferably 105 Å to 300 Å, most preferably 115 Å to 250 Å. In embodiments where the protective coating 320 has both a first protective metal nitride 322 film and a second protective film 324, the metal oxynitride film of the top layer 300 can have a thickness of 50 Å to 280 Å, preferably 75 Å to 260 Å, more preferably 100 Å to 240 Å, most preferably 120 Å to 220 Å.

In certain embodiments, the invention has a combined thickness of the metal oxynitride film of the top layer 300 (if present) and/or the first protective metal nitride film 322 (if present) of between 200 Å and 800 Å, for example, 320 Å to 800 Å, 320 Å to 380 Å, or 280 Å to 370 Å.

In certain embodiments, the protective coating 300 can comprise a second protective film 324 comprising TiAlO. Non-limiting examples of the second protective film 324 may have a thickness range of such as, 100 Å to 400 Å, such as, 200 Å to 370 Å, such as, 245 Å to 300 Å, such as, 285 Å to 300 Å. It is to be understood that the second protective film 324 may be applied, e.g., as the top-most layer, to any other configuration of the top layer, metal nitride films, and metal oxynitride films consistent with the present disclosure. Alternatively, additional functional layers or protective layers may be applied over the second protective film 324 (not shown). This additional protective film can be any of the materials used to form the protective coating 320, or the second protective film 324, or any material that may be used as a topcoat. Similarly, it is to be understood that a coated article need not include a second protective film 324.

The outermost protective coating 320 has a total thickness (i.e. the sum of all of the thickness of the layers or films within the protective coating 320) in the range of 200 Å to 800 Å, preferably 300 Å to 700 Å, more preferably 350 Å to 600 Å, or most preferably 400 Å to 550 Å.

In the practice of the invention, by selecting a particular metal for the metallic layers, selecting a primer material and thickness, and selecting dielectric material(s) and thickness, the absorbed color (e.g., tint) of the coating can be varied. In the practice of the invention, it is desired to maintain the color of the coated article before and after tempering.

Color values (e.g., L*, a*, b*, C*, and hue^{o}) are in accordance with the 1976 CIELAB color system specified by the International Commission on Illumination. The L*, a*, and b* values in the specification and claims represent color center point values. “Rf” refers to the film side reflectance, “Rg” refers to the glass side reflectance, and “T” refers to the transmittance through the article.

A reference IGU (3 mm or 6 mm) or reference laminated unit incorporating the solar control coating of the invention within normal manufacturing variation should have a ΔEcmc color difference, relative to the center point value, of less than <4.5 CMC units (i.e., ΔEcmc<4.5), preferably less than <4 CMC units (i.e., ΔEcmc<4) after heat treatment.

A coated article includes a blocking layer 220 deposited over at least a portion of a major surface of a substrate 210. The blocking layer 220 can reduce dendrite formation in the metallic layer and reduce red haze in the coated article after tempering.

One non-limiting embodiment is a method of reducing dendrite formation in a metallic layer. By “dendrite” is meant a branching, tree-like feature in or on the metallic layer. For example, the dendrite can be a crystal or a crystal mass. These dendrites are crystal structures that are typically formed in or on the metallic layer during the tempering process. To reduce the formation of dendrites in the metallic layer, a substrate is provided. The substrate can be any of the substrates as described herein. The substrate has a first surface and a second surface opposite the first surface. A blocking layer is formed over at least a portion of the first surface of the second surface. The blocking layer can be any of the blocking layers as described herein. A metallic layer is formed over at least a portion of the blocking layer. The metallic layer can be any metallic layer as described herein. A top layer is formed over at least a portion of the metallic layer. The top layer can be any top layer as described herein. The forming of the blocking layer, metallic layer and top layer creates a coated article. The coated article may further comprise additional layers, as described herein. The coated article is tempered, wherein the dendrite formation in the metallic layer is reduced in comparison to a coated article without the blocking layer.

Another non-limiting embodiment is a method of reducing red haze in a coated article. Dendrites that form within the metallic layer, as described herein above, can be light scattering features, where light scattering features increase the haze (i.e, light scattering) of the coated article. Dendrites within the metallic layer cause the light waves of electromagnetic energy to travel more randomly and disrupt the waveguide effect, which increases the amount of electromagnetic energy that passes through the metallic layer, into the substrate, and then exits the bottom surface of the substrate. “Red haze” as described herein relates to a light scattering effect which is visible if a coated article is illuminated by a bright light in front of a dark background. The red haze is formed as a result of voids (depletions or vacancies) that form in the metallic layer during the tempering or heat strengthening process. Alkali metal mobility in the glass and the coating stack during heating leads to nucleation and growth that results in dendrite formation, which leads to a coated substrate having red haze. The red haze is reduced by forming a blocking layer over a substrate. The blocking layer can be any of the blocking layers described herein. A metallic layer is formed over at least a portion of the blocking layer. The metallic layer can be any metallic layer described herein. A top layer is formed over at least a portion of the metallic layer. The top layer can be any top layer described herein. The forming of the blocking layer, metallic layer and top layer creates a coated article. The coated article may comprise additional layers as described herein. The coated article is tempered, wherein the red haze in the coated article is less than the red haze in a coated article without a blocking layer.

The following numbered clauses are illustrative of various aspects of the invention:

Clause 1: A coated article comprising a substrate comprising a first surface and second surface opposite the first surface; and a functional coating applied over the first surface or the second surface, the functional coating comprising a blocking layer over at least a portion of the substrate; a metallic layer over at least a portion of the blocking layer; and a top layer over at least a portion of the metallic layer.

Clause 2: The coated article of clause 1, wherein the coated article is temperable.

Clause 3: The coated article of clauses 1 or 2, wherein the blocking layer comprises a first film, a second film, and third film.

Clause 4: The coated article of any of the preceding clauses, wherein the first film of the blocking layer is a blocking film.

Clause 5: The coated article of any of the preceding clauses, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 6: The coated article of any of the preceding clauses, wherein the blocking film comprises silicon oxide, silicon aluminum oxide, silicon oxynitride, silicon aluminum oxynitride, or combinations thereof.

Clause 7: The coated article of any of the preceding clauses, wherein the blocking film comprises silicon aluminum oxynitride.

Clause 8: The coated article any of the preceding clauses, wherein the second film comprises zinc stannate over at least a portion of the blocking film, and the third film comprises zinc oxide over at least a portion of the second film.

Clause 9: The coated article of clause 7, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 10: The coated article of clause 7, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 11: The coated article of any of the clauses 1-8, wherein the blocking film has an oxygen to nitrogen ratio of 20% to 50% oxygen to 80% to 50% nitrogen, comprises from 20 wt. % to 25 wt. % aluminum and comprises 80 wt. % to 75 wt. % silicon.

Clause 12: The coated article of clause 11, wherein the optical index of refraction is 1.70 to 1.80.

Clause 13: The coated article of clauses 3 to 12, wherein the blocking film comprises a total thickness of 50 Å to 350 Å, preferably 50 Å to 300 Å, or most preferably 100 Å to 250 Å.

Clause 14: The coated article of any of the preceding clauses, wherein the blocking layer comprises a total thickness of 150 Å to 850 Å, preferably 250 Å to 600 Å, or most preferably 200 Å to 500 Å.

Clause 15: The coated article of any of the preceding clauses, wherein the metallic layer comprises silver, gold, palladium, copper, alloys thereof, mixtures thereof, or combinations thereof.

Clause 16: The coated article of clause 15, wherein the metallic layer comprises silver.

Clause 17: The coated article of any of the preceding clauses, wherein the metallic layer is a continuous metallic layer.

Clause 18: The coated article of any of the preceding clauses, wherein the metallic layer comprises a total thickness of 60 Å to 150 Å, preferably 60 Å to 100 Å, or most preferably 60 Å to 90 Å.

Clause 19: The coated article of any of the preceding clauses, wherein the top layer comprises a first film and a second film.

Clause 20: The coated article of clause 19, wherein the first film of the top layer comprises zinc stannate over at least a portion of the metallic layer and the second film comprises silicon aluminum oxynitride over at least a portion of the first film.

Clause 21: The coated article of any of the preceding clauses, wherein the top layer comprises a total thickness of 50 Å to 750 Å, preferably 250 Å to 600 Å, more preferably 300 Å to 550 Å, or most preferably 300 Å to 400 Å.

Clause 22: The coated article of any of the preceding clauses, further comprising a first primer layer formed over the metallic layer.

Clause 23: The coated article of clause 22, wherein the primer layer is selected from a group consisting of titanium, silicon, nickel, zirconium, zinc, aluminum, cobalt, chromium, aluminum, an alloy thereof or a mixture thereof.

Clause 24: The coated article of clause 22, wherein the primer layer comprises a total thickness of 5 Å to 50 Å, preferably 10 Å to 35 Å, or more preferably 10 Å to 30 Å

Clause 25: The coated article of any of the preceding clauses, further comprising an outermost protective coating comprising a protective layer, wherein the protective layer comprises at least one of Si₃N₄, SiAlN, SiAlON, TIAIO, titania, alumina, silica, zirconia, or combinations thereof.

Clause 26: The coated article of clause 25, wherein the protective layer comprises a first protective film and a second protective film, wherein the second protective film is positioned over at least a portion of the first protective film.

Clause 27: The coated article of clause 26, wherein the first protective film comprises SiAlN.

Clause 28: The coated article of claim 26, wherein the second protective film comprises TiAlO.

Clause 29: The coated article of clause 25, wherein the outermost protective coating comprises a total thickness of 200 Å to 800 Å, preferably 300 Å to 700 Å, more preferably 350 Å to 600 Å, or most preferably 400 Å to 550 Å.

Clause 30: The coated article of clause 1, wherein the functional coating applied over the surface further comprises a first middle layer over at least a portion of the metallic layer; and a second metallic layer over at least a portion of the middle layer, wherein the top layer is over at least a portion of the second metallic layer.

Clause 31: The coated article of clause 30, wherein the first middle layer comprises a first film, a second film, and a third film.

Clause 32: The coated article of clauses 30 and 31, wherein the first film of the first middle layer comprises zinc oxide over at least a portion of the metallic layer, the second film comprises zinc stannate over at least a portion of the first film, and the third film comprises zinc oxide over at least a portion of the second film.

Clause 33: The coated article of clauses 30 to 32, wherein the first middle layer comprises a total thickness of 50 Å to 500 Å, preferably 100 Å to 300 Å, more preferably, 100 Å to 200 Å, or most preferably, 150 Å to 200 Å.

Clause 34: The coated article of clause 30, wherein the second metallic layer is a continuous layer and comprises a total thickness of 60 Å to 150 Å, preferably, 60 Å to 100 Å, or most preferably 60 Å to 90 Å.

Clause 35: The coated article of clause 34, wherein the second metallic layer is a discontinuous layer and comprises a total thickness of less than 90 Å.

Clause 36: The coated article of claims 30 to 35, further comprising a second primer layer formed over the second metallic layer.

Clause 37: The coated article of clause 1, wherein the functional coating applied over the surface further comprises a first middle layer over at least a portion of the metallic layer; a second metallic layer over at least a portion of the first middle layer; a second middle layer over at least a portion of the second metallic layer; and a third metallic layer over at least a portion of the second middle layer, wherein the top layer is over at least a portion of the third metallic layer.

Clause 38: The coated article of clause 37, wherein the second middle layer comprises a first film, a second film, and a third film.

Clause 39: The coated article of clauses 37 and 38, wherein the first film of the second middle layer comprises zinc oxide over at least a portion of the second metallic layer, the second film comprises zinc stannate over at least a portion of the first film, and the third film comprises zinc oxide over at least a portion of the second film.

Clause 40: The coated article of clauses 37 to 39, wherein the second middle layer comprises a total thickness of 200 Å to 1000 Å, preferably 400 Å to 900 Å, more preferably 650 Å to 800 Å, or most preferably 690 Å to 720 Å.

Clause 41: The coated article of clauses 37 to 40, wherein the third metallic layer is a continuous layer and comprises a total thickness of 60 Å to 150 Å, preferably, 60 Å to 100 Å, or most preferably, 60 Å to 90 Å.

Clause 42: The coated article of clauses 37 to 40, wherein the third metallic layer is a discontinuous layer and comprises a total thickness comprises a total thickness of less than 90 Å.

Clause 43: The coated article of clauses 37 to 42, further comprising a third primer layer formed over the third metallic layer.

Clause 44: The coated article of clause 1, wherein the coating applied over the surface further comprises a first middle layer over at least a portion of the metallic layer; a second metallic layer over at least a portion of the first middle layer; a second middle layer over at least a portion of the second metallic layer; a third metallic layer over at least a portion of the second middle layer; a third middle layer over at least a portion of the third metallic layer; and a fourth metallic layer over at least a portion of the third middle layer, wherein the top layer is over at least a portion of the fourth metallic layer.

Clause 45: The coated article of clause 44, wherein the third middle layer comprises a first film, a second film, and a third film.

Clause 46: The coated article of clauses 44 to 45, wherein the first film of the third middle layer comprises zinc oxide over at least a portion of the third metallic layer, the second film comprises zinc stannate over at least a portion of the first film, and the third film comprises zinc oxide over at least a portion of the second film.

Clause 47: The coated article of clauses 44 to 46, wherein the third middle layer comprises a total thickness of 200 Å to 1000 Å, preferably 400 Å to 900 Å, more preferably, 650 Å to 800 Å, or most preferably, 690 Å to 720 Å.

Clause 48: The coated article of clause 44, wherein the fourth metallic layer is a continuous layer and comprises a total thickness of 60 Å to 150 Å, preferably 60 Å to 100 Å, or most preferably 60 Å to 90 Å.

Clause 49: The coated article of clauses 44 to 48, further comprising a fourth primer layer formed over the fourth metallic layer.

Clause 50: A method of making a coated article comprising providing a substrate comprising a first surface and second surface opposite the first surface; forming a blocking layer over at least a portion of the first surface or the second surface; forming a metallic layer over at least a portion of the blocking layer; and forming a top layer over at least a portion of the metallic layer, wherein the coated article has an optical color shift, as measured by ΔEcmc, of no more than 4.5 after tempering.

Clause 51: The method of clause 50, wherein the blocking layer comprises a first film, a second film, and third film.

Clause 52: The method of clause 51, wherein the first film of the blocking layer is a blocking film.

Clause 53: The method of clause 52, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 54: The method of clause 52, wherein the blocking film comprises silicon oxide, silicon aluminum oxide, silicon oxynitride, silicon aluminum oxynitride, or combinations thereof.

Clause 55: The method of clauses 53 or 54, where the blocking film comprises silicon aluminum oxynitride.

Clause 56: The method of clause 51, wherein the second film comprises zinc stannate over at least a portion of the blocking film, and the third film comprises zinc oxide over at least a portion of the second film.

Clause 57: The method of clause 55, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 58: The method of clause 55, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 59: The method of any of clauses 37 to 58, wherein the blocking film has an oxygen to nitrogen ratio of 20% to 50% oxygen to 80% to 50% nitrogen, comprises from 20 wt. % to 25 wt. % aluminum, and comprises 80 wt. % to 75 wt. % silicon.

Clause 60: The method of clause 59, wherein the optical index of refraction is 1.70 to 1.80.

Clause 61: The method of clauses 52 to 60, wherein the blocking film comprises a total thickness of 50 Å to 350 Å, preferably 50 Å to 300 Å, or most preferably, 100 Å to 250 Å.

Clause 62: The method of clauses 50 to 61, wherein the blocking layer comprises a total thickness of 150 Å to 850 Å, preferably 250 Å to 600 Å, or most preferably, 200 Å to 500 Å.

Clause 63: The method of clauses 50 to 62, wherein the metallic layer comprises silver, gold, palladium, copper, alloys thereof, mixtures thereof, or combinations thereof.

Clause 64: The method of clause 63, wherein the metallic layer comprises silver.

Clause 65: The method of clauses 50 to 64, wherein the metallic layer is a continuous metallic layer.

Clause 66: The method of clauses 50 to 65, wherein the metallic layer comprises a total thickness of 60 Å to 150 Å, preferably 60 Å to 100 Å, or most preferably, 60 Å to 90 Å.

Clause 67: The method of clauses 50 to 66, wherein the top layer comprises a first film and a second film.

Clause 68: The method of clause 67, wherein the first film of the top layer comprises zinc stannate over at least a portion of the metallic layer and the second film comprises silicon aluminum oxynitride over at least a portion of the first film.

Clause 69: The method of clauses 50 to 68, wherein the top layer comprises a total thickness of 50 Å to 750 Å, preferably 250 Å to 600 Å, more preferably, 300 Å to 550 Å, or most preferably, 300 Å to 400 Å.

Clause 70: The method of clause 50, wherein the coated article has an optical color shift, as measured by ΔEcmc, of no more than 4.0 after tempering.

Clause 71: A method of reducing dendrite formation in a metallic layer of a coated article, the method comprising: providing a substrate comprising a first surface and second surface opposite the first surface; forming a blocking layer over at least a portion of the first surface or the second surface; forming a metallic layer over at least a portion of the blocking layer; and forming a top layer over at least a portion of the metallic layer, thereby forming the coated article, and tempering the coated article, wherein the coated article has reduced dendrite formation in the metallic layer after tempering.

Clause 72: The method of clause 71, wherein the blocking layer comprises a first film, a second film, and third film.

Clause 73: The method of clause 72, wherein the first film of the blocking layer is a blocking film.

Clause 74: The method of clause 73, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 75: The method of clause 73, wherein the blocking film comprises silicon oxide, silicon aluminum oxide, silicon oxynitride, silicon aluminum oxynitride, or combinations thereof.

Clause 76: The method of clauses 74 or 75, where the blocking film comprises silicon aluminum oxynitride.

Clause 77: The method of clause 76, wherein the second film comprises zinc stannate over at least a portion of the blocking film, and the third film comprises zinc oxide over at least a portion of the second film.

Clause 78: The method of clause 76, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 79: The method of clause 76, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 80: The method of any of clauses 71 to 79, wherein the blocking film has an oxygen to nitrogen ratio of 20% to 50% oxygen to 80% to 50% nitrogen, comprises from 20 wt. % to 25 wt. % aluminum, and comprises 80 wt. % to 75 wt. % silicon.

Clause 81: The method of clause 80, wherein the optical index of refraction is 1.70 to 1.80.

Clause 82: The method of clauses 73 to 81, wherein the blocking film comprises a total thickness of 50 Å to 350 Å, preferably 50 Å to 300 Å, or most preferably, 100 Å to 250 Å.

Clause 83: The method of clauses 71 to 82, wherein the blocking layer comprises a total thickness of 150 Å to 850 Å, preferably, 250 Å to 600 Å, or most preferably, 200 Å to 500 Å.

Clause 84: The method of clauses 71 to 83, wherein the metallic layer comprises silver, gold, palladium, copper, alloys thereof, mixtures thereof, or combinations thereof.

Clause 85: The method of clause 84, wherein the metallic layer comprises silver.

Clause 86: The method of clauses 71 to 85, wherein the metallic layer is a continuous metallic layer.

Clause 87: The method of clauses 71 to 86, wherein the metallic layer comprises a total thickness of 60 Å to 150 Å, preferably, 60 Å to 100 Å, or most preferably, 60 Å to 90 Å.

Clause 88: The method of clauses 71 to 87, wherein the top layer comprises a first film and a second film.

Clause 89: The method of clause 88, wherein the first film of the top layer comprises zinc stannate over at least a portion of the metallic layer and the second film comprises silicon aluminum oxynitride over at least a portion of the first film.

Clause 90: The method of clauses 71 to 89, wherein the top layer comprises a total thickness of 50 Å to 750 Å, preferably 250 Å to 600 Å, more preferably, 300 Å to 550 Å, or most preferably, 300 Å to 400 Å.

Clause 91: A method of reducing red haze of a coated article, the method comprising: providing a substrate comprising a first surface and second surface opposite the first surface; forming a blocking layer over at least a portion of the first surface or the second surface; forming a metallic layer over at least a portion of the blocking layer; and forming a top layer over at least a portion of the metallic layer, thereby forming the coated article and tempering the coated article, wherein the coated article has reduced red haze after tempering.

Clause 92: The method of clause 91, wherein the blocking layer comprises a first film, a second film, and third film.

Clause 93: The method of clause 92, wherein the first film of the blocking layer is a blocking film.

Clause 94: The method of clause 93, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 95: The method of clause 93, wherein the blocking film comprises silicon oxide, silicon aluminum oxide, silicon oxynitride, silicon aluminum oxynitride, or combinations thereof.

Clause 96: The method of clauses 94 or 95, wherein the blocking film comprises silicon aluminum oxynitride.

Clause 97: The method of clause 96, wherein the second film comprises zinc stannate over at least a portion of the blocking film, and the third film comprises zinc oxide over at least a portion of the second film.

Clause 98: The method of clause 96, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 99: The method of clause 96, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 100: The method of any of clauses 91 to 99, wherein the blocking film has an oxygen to nitrogen ratio of 20% to 50% oxygen to 80% to 50% nitrogen, comprises from 20 wt. % to 25 wt. % aluminum, and comprises 80 wt. % to 75 wt. % silicon.

Clause 101: The method of clause 100, wherein the optical index of refraction is 1.70 to 1.80.

Clause 102: The method of clauses 93 to 101, wherein the blocking film comprises a total thickness of 50 Å to 350 Å, preferably, 50 Å to 300 Å, or most preferably, 100 Å to 250 Å.

Clause 103: The method of clauses 91 to 102, wherein the blocking layer comprises a total thickness of 150 Å to 850 Å, preferably, 250 Å to 600 Å, or most preferably, 200 Å to 500 Å.

Clause 104: The method of clauses 91 to 103, wherein the metallic layer comprises silver, gold, palladium, copper, alloys thereof, mixtures thereof, or combinations thereof.

Clause 105: The method of clause 104, wherein the metallic layer comprises silver.

Clause 106: The method of clauses 91 to 105, wherein the metallic layer is a continuous metallic layer.

Clause 107: The method of clauses 91 to 106, wherein the metallic layer comprises a total thickness of 60 Å to 150 Å, preferably, 60 Å to 100 Å, or most preferably, 60 Å to 90 Å.

Clause 108: The method of clauses 91 to 107, wherein the top layer comprises a first film and a second film.

Clause 109: The method of clause 108, wherein the first film of the top layer comprises zinc stannate over at least a portion of the metallic layer and the second film comprises silicon aluminum oxynitride over at least a portion of the first film.

Clause 110: The method of clauses 91 to 109, wherein the top layer comprises a total thickness of 50 Å to 750 Å, preferably, 250 Å to 600 Å, more preferably, 300 Å to 550 Å, or most preferably, 300 Å to 400 Å.

Clause 111: An insulated glass unit comprising a first ply comprising a No. 1 surface and a No. 2 surface opposing the No. 1 surface; a second ply comprising a No. 3 surface and a No. 4 surface, wherein the second ply is spaced from the first ply, and wherein the first ply and second ply are connected together; and a functional coating over at least a portion of the No. 3 surface or the No. 4 surface, the functional coating comprising a blocking layer over at least a portion of the No. 3 surface or the No. 4 surface; a metallic layer over at least a portion of the blocking layer; and a top layer over at least a portion of the metallic layer.

Clause 112: The insulated glass unit of clause 111, wherein the blocking layer comprises a first film, a second film, and third film.

Clause 113: The insulated glass unit of clause 112, wherein the first film of the blocking layer is a blocking film.

Clause 114: The insulated glass unit of clause 113, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 115: The insulated glass unit of clause 113, wherein the blocking film comprises silicon oxide, silicon aluminum oxide, silicon oxynitride, silicon aluminum oxynitride, or combinations thereof.

Clause 116: The insulated glass unit of clauses 114 or 115, where the blocking film comprises silicon aluminum oxynitride.

Clause 117: The insulated glass unit of clause 113, wherein the second film comprises zinc stannate over at least a portion of the blocking film, and the third film comprises zinc oxide over at least a portion of the second film.

Clause 118: The insulated glass unit of clause 116, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 119: The insulated glass unit of clause 116, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 120: The insulated glass unit of any of clauses 111 to 119, wherein the blocking film has an oxygen to nitrogen ratio of 20% to 50% oxygen to 80% to 50% nitrogen, comprises from 20 wt. % to 25 wt. % aluminum, and comprises 80 wt. % to 75 wt. % silicon.

Clause 121: The insulated glass unit of clause 120, wherein the optical index of refraction is 1.70 to 1.80.

Clause 122: The insulated glass unit of clauses 113 to 121, wherein the blocking film comprises a total thickness of 50 Å to 350 Å, preferably 50 Å to 300 Å, or most preferably 100 Å to 250 Å.

Clause 123: The insulated glass unit of clauses 111 to 122, wherein the blocking layer comprises a total thickness of 150 Å to 850 Å, preferably 250 Å to 600 Å, or most preferably 200 Å to 500 Å.

Clause 124: The insulated glass unit of clauses 111 to 123, wherein the metallic layer comprises silver, gold, palladium, copper, alloys thereof, mixtures thereof, or combinations thereof.

Clause 125: The insulated glass unit of clause 124, wherein the metallic layer comprises silver.

Clause 126: The insulated glass unit of clauses 111 to 125, wherein the metallic layer is a continuous metallic layer.

Clause 127: The insulated glass unit of clauses 111 to 126, wherein the metallic layer comprises a total thickness of 60 Å to 150 Å, preferably 60 Å to 100 Å, or most preferably 60 Å to 90 Å.

Clause 128: The insulated glass unit of clauses 111 to 127, wherein the top layer comprises a first film and a second film.

Clause 129: The insulated glass unit of clause 128, wherein the first film of the top layer comprises zinc stannate over at least a portion of the metallic layer and the second film comprises silicon aluminum oxynitride over at least a portion of the first film.

Clause 130: The insulated glass unit of clauses 111 to 129, wherein the top layer comprises a total thickness of 50 Å to 750 Å, preferably 250 Å to 600 Å, more preferably 300 Å to 550 Å, or most preferably 300 Å to 400 Å.

Clause 131: A method of making a coated article comprising: providing a coated article comprising a first surface and second surface opposite the first surface, wherein the coated article comprises a blocking layer over at least a portion of the first surface or the second surface; a metallic layer over at least a portion of the blocking layer; and a top layer over at least a portion of the metallic layer; and tempering the coated article, wherein the coated article has an optical color shift, as measured by ΔEcmc, of no more than 4.5 after tempering.

Clause 132: The method of clause 131, wherein the blocking layer comprises a first film, a second film, and third film.

Clause 133: The method of clause 132, wherein the first film of the blocking layer is a blocking film.

Clause 134: The method of clause 133, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 135: The method of clause 134, wherein the blocking film comprises silicon oxide, silicon aluminum oxide, silicon oxynitride, silicon aluminum oxynitride, or combinations thereof.

Clause 136: The method of clauses 134 or 135, where the blocking film comprises silicon aluminum oxynitride.

Clause 137: The method of clause 132, wherein the second film comprises zinc stannate over at least a portion of the blocking film, and the third film comprises zinc oxide over at least a portion of the second film.

Clause 138: The method of clause 136, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 139: The method of clause 136, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 140: The method of any of clauses 131 to 139, wherein the blocking film has an oxygen to nitrogen ratio of 20% to 50% oxygen to 80% to 50% nitrogen, comprises from 20 wt. % to 25 wt. % aluminum, and comprises 80 wt. % to 75 wt. % silicon.

Clause 141: The method of clause 136, wherein the optical index of refraction is 1.70 to 1.80.

Clause 142: The method of clauses 133 to 141, wherein the blocking film comprises a total thickness of 50 Å to 350 Å, preferably 50 Å to 300 Å, or most preferably, 100 Å to 250 Å.

Clause 143: The method of clauses 131 to 142, wherein the blocking layer comprises a total thickness of 150 Å to 850 Å, preferably 250 Å to 600 Å, or most preferably, 200 Å to 500 Å.

Clause 144: The method of clauses 131 to 143, wherein the metallic layer comprises silver, gold, palladium, copper, alloys thereof, mixtures thereof, or combinations thereof.

Clause 145: The method of clause 144, wherein the metallic layer comprises silver.

Clause 146: The method of clauses 131 to 145, wherein the metallic layer is a continuous metallic layer.

Clause 147: The method of clauses 131 to 146, wherein the metallic layer comprises a total thickness of 60 Å to 150 Å, preferably 60 Å to 100 Å, or most preferably, 60 Å to 90 Å.

Clause 148: The method of clauses 131 to 147, wherein the top layer comprises a first film and a second film.

Clause 149: The method of clause 148, wherein the first film of the top layer comprises zinc stannate over at least a portion of the metallic layer and the second film comprises silicon aluminum oxynitride over at least a portion of the first film.

Clause 150: The method of clauses 131 to 149, wherein the top layer comprises a total thickness of 50 Å to 750 Å, preferably 250 Å to 600 Å, more preferably, 300 Å to 550 Å, or most preferably, 300 Å to 400 Å.

Clause 151: The method of clause 131, wherein the coated article has an optical color shift, as measured by ΔEcmc, of no more than 4.0 after tempering.

Clause 152: A method of reducing dendrite formation in a metallic layer of a coated article, the method comprising: providing a coated article comprising a first surface and second surface opposite the first surface; a blocking layer over at least a portion of the first surface or the second surface; a metallic layer over at least a portion of the blocking layer; and forming a top layer over at least a portion of the metallic layer; and tempering the coated article, wherein the coated article has reduced dendrite formation in the metallic layer after tempering.

Clause 153: The method of clause 152, wherein the blocking layer comprises a first film, a second film, and third film.

Clause 154: The method of clause 153, wherein the first film of the blocking layer is a blocking film.

Clause 155: The method of clause 154, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 156: The method of clause 155, wherein the blocking film comprises silicon oxide, silicon aluminum oxide, silicon oxynitride, silicon aluminum oxynitride, or combinations thereof.

Clause 157: The method of clauses 155 or 156, where the blocking film comprises silicon aluminum oxynitride.

Clause 158: The method of clause 153, wherein the second film comprises zinc stannate over at least a portion of the blocking film, and the third film comprises zinc oxide over at least a portion of the second film.

Clause 159: The method of clause 157, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 160: The method of clause 157, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 161: The method of any of clauses 153 to 160, wherein the blocking film has an oxygen to nitrogen ratio of 20% to 50% oxygen to 80% to 50% nitrogen, comprises from 20 wt. % to 25 wt. % aluminum, and comprises 80 wt. % to 75 wt. % silicon.

Clause 162: The method of clause 157, wherein the optical index of refraction is 1.70 to 1.80.

Clause 163: The method of clauses 153 to 162, wherein the blocking film comprises a total thickness of 50 Å to 350 Å, preferably 50 Å to 300 Å, or most preferably, 100 Å to 250 Å.

Clause 164: The method of clauses 152 to 163, wherein the blocking layer comprises a total thickness of 150 Å to 850 Å, preferably, 250 Å to 600 Å, or most preferably, 200 Å to 500 Å.

Clause 165: The method of clauses 152 to 164, wherein the metallic layer comprises silver, gold, palladium, copper, alloys thereof, mixtures thereof, or combinations thereof.

Clause 166: The method of clause 165, wherein the metallic layer comprises silver.

Clause 167: The method of clauses 152 to 166, wherein the metallic layer is a continuous metallic layer.

Clause 168: The method of clauses 152 to 167, wherein the metallic layer comprises a total thickness of 60 Å to 150 Å, preferably, 60 Å to 100 Å, or most preferably, 60 Å to 90 Å.

Clause 169: The method of clauses 152 to 168, wherein the top layer comprises a first film and a second film.

Clause 170: The method of clause 169, wherein the first film of the top layer comprises zinc stannate over at least a portion of the metallic layer and the second film comprises silicon aluminum oxynitride over at least a portion of the first film.

Clause 171: The method of clauses 152 to 170, wherein the top layer comprises a total thickness of 50 Å to 750 Å, preferably 250 Å to 600 Å, more preferably, 300 Å to 550 Å, or most preferably, 300 Å to 400 Å.

Clause 172: A method of reducing red haze of a coated article, the method comprising: providing a coated article comprising a first surface and second surface opposite the first surface; a blocking layer over at least a portion of the first surface or the second surface; a metallic layer over at least a portion of the blocking layer; and forming a top layer over at least a portion of the metallic layer; and tempering the coated article, wherein the coated article has reduced dendrite formation in the metallic layer after tempering.

Clause 173: The method of clause 172, wherein the blocking layer comprises a first film, a second film, and third film.

Clause 174: The method of clause 173, wherein the first film of the blocking layer is a blocking film.

Clause 175: The method of clause 174, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

Clause 176: The method of clause 175, wherein the blocking film comprises silicon oxide, silicon aluminum oxide, silicon oxynitride, silicon aluminum oxynitride, or combinations thereof.

Clause 177: The method of clauses 175 or 176, where the blocking film comprises silicon aluminum oxynitride.

Clause 178: The method of clause 173, wherein the second film comprises zinc stannate over at least a portion of the blocking film, and the third film comprises zinc oxide over at least a portion of the second film.

Clause 179: The method of clause 177, wherein the blocking film has an oxygen to nitrogen ratio of 0% to 50% oxygen to 100% to 50% nitrogen, 10 to 50% oxygen to 90% to 50% nitrogen, 15% to 40% oxygen to 85% to 60% nitrogen, or 20% to 50% oxygen to 80% to 50% nitrogen.

Clause 180: The method of clause 177, wherein the blocking film comprises from 5 wt. % to 20 wt. % aluminum and 95 wt. % to 80 wt. % silicon, 10 wt. % to 20 wt. % aluminum and 90 wt. % to 80 wt. % silicon, or 20 wt. % to 25 wt. % aluminum and 80 wt. % to 75 wt. % silicon.

Clause 181: The method of any of clauses 173 to 180, wherein the blocking film has an oxygen to nitrogen ratio of 20% to 50% oxygen to 80% to 50% nitrogen, comprises from 20 wt. % to 25 wt. % aluminum, and comprises 80 wt. % to 75 wt. % silicon.

Clause 182: The method of clause 177, wherein the optical index of refraction is 1.70 to 1.80.

Clause 183: The method of clauses 173 to 182, wherein the blocking film comprises a total thickness of 50 Å to 350 Å, preferably 50 Å to 300 Å, or most preferably, 100 Å to 250 Å.

Clause 184: The method of clauses 172 to 163, wherein the blocking layer comprises a total thickness of 150 Å to 850 Å, preferably, 250 Å to 600 Å, or most preferably, 200 Å to 500 Å.

Clause 185: The method of clauses 172 to 184, wherein the metallic layer comprises silver, gold, palladium, copper, alloys thereof, mixtures thereof, or combinations thereof.

Clause 186: The method of clause 185, wherein the metallic layer comprises silver.

Clause 187: The method of clauses 172 to 186, wherein the metallic layer is a continuous metallic layer.

Clause 188: The method of clauses 172 to 187, wherein the metallic layer comprises a total thickness of 60 Å to 150 Å, preferably, 60 Å to 100 Å, or most preferably, 60 Å to 90 Å.

Clause 189: The method of clauses 172 to 188, wherein the top layer comprises a first film and a second film.

Clause 190: The method of clause 189, wherein the first film of the top layer comprises zinc stannate over at least a portion of the metallic layer and the second film comprises silicon aluminum oxynitride over at least a portion of the first film.

Clause 191: The method of clauses 172 to 190, wherein the top layer comprises a total thickness of 50 Å to 750 Å, preferably 250 Å to 600 Å, more preferably, 300 Å to 550 Å, or most preferably, 300 Å to 400 Å.

### EXAMPLES

### Example 1

A substrate was coated with a functional coating according to Table 1. The substrate was glass. The functional layer included a blocking layer disposed over the substrate, where the blocking layer comprised a blocking film as the first film, a metallic layer, a primer layer, a top layer, and optionally a protective film. The blocking film of the blocking layer comprised silicon aluminum oxide (SiAlO). The blocking layer further comprised a zinc stannate film and a zinc oxide film. The top layer comprised a zinc stannate film and a silicon aluminum oxynitride film. An optional protective film comprising SiAlN or TiAlO was disposed over the silicon aluminum oxynitride film of the top layer and an optional second protective film comprising TiAlO was disposed over the first protective film comprising SiAlN. Comparative Examples CE-1, CE-2, CE-3, CE-4, and CE-5 were prepared according to Table 2 without blocking films.

TABLE 1

| Sample No. | 1 | 2 |
|---|---|---|
| Substrate | Glass | Glass |
| Blocking Layer- Blocking film | SiAlO | SiAlO |
| Blocking Layer - 2^{nd} film | Zinc Stannate | Zinc Stannate |
| Blocking Layer - 3^{rd} film | Zinc Oxide | Zinc Oxide |
| Top Layer - 1^{st} Film | Zinc Stannate | Zinc Stannate |
| Top Layer - 2^{nd} film | SiAlON | SiAlON |
| 1^{st} Protective Film | SiAlN | TiAlO |
| 2^{nd} Protective Film | TiAlO | N/A |

TABLE 2

| | CE-1 | CE-2 | CE-3 | CE-4 | CE-5 |
|---|---|---|---|---|---|
| Substrate | Glass | | | | |
| 1^{st} dielectric film | Zinc | Zinc | Zinc | Zinc | Zinc |
| | Stannate | Stannate | Stannate | Stannate | Stannate |
| 2^{nd} dielectric film | Zinc Oxide | Zinc Oxide | Zinc Oxide | Zinc Oxide | Zinc Oxide |
| Top Layer- 1^{st} Film | N/A | Zinc | Zinc | Zinc | Zinc |
| | | Stannate | Stannate | Stannate | Stannate |
| Top Layer- 2^{nd} film | N/A | N/A | SiAlON | SiAlON | SiAlON |
| Protective Film | N/A | N/A | N/A | SiAlN | TiAlO |

The resulting color properties of the coated articles can be found in Table 3.

TABLE 3

| | ΔEcmc | | |
|---|---|---|---|
| Sample | Rf | Rg | T |
| 1 | 4.40 | 3.64 | 1.78 |
| 2 | 1.15 | 1.05 | 0.74 |
| CE-1 | 1.86 | 1.75 | 1.16 |
| CE-2 | 2.01 | 2.03 | 1.24 |
| CE-3 | 2.67 | 2.77 | 0.85 |
| CE-4 | 4.57 | 4.48 | 1.41 |
| CE-5 | 3.71 | 3.72 | 2.59 |

### Example 2

A substrate was coated with a functional coating as disclosed in Table 4. The substrate was glass. The functional layer included a blocking layer disposed over the substrate, where the blocking layer comprised a blocking film as the first film, a metallic layer, a primer layer, a top layer, and optionally a protective film. The blocking film of the blocking layer comprised silicon aluminum nitride (SiAlN) or silicon aluminum oxynitride (SiAlON). The blocking layer further comprised a zinc stannate film and a zinc oxide film. The metallic layer was disposed over the zinc oxide film of the blocking layer. The metallic layer is a continuous silver layer. A primer layer was disposed over the metallic layer, and a top layer was disposed over the primer layer. The top layer comprised a zinc stannate film and a silicon aluminum oxynitride film. An optional protective film comprising SiAlN was disposed over the SiAlON film of the top layer. Comparative Examples CE-1 and CE-2, were prepared according to Table 5 without a blocking film, just a first and second dielectric film of zinc stannate and zinc oxide, respectively.

TABLE 4

| Sample No. | 3 | 4 | 5 | 6 |
|---|---|---|---|---|
| Substrate | Glass | Glass | Glass | Glass |
| Blocking Layer- | SiAlN | SiAlN | SiAlON | SiAlON |
| Blocking film | | | | |
| Blocking Layer- | Zinc Stannate | Zinc Stannate | Zinc Stannate | Zinc Stannate |
| 2^{nd} film | | | | |
| Blocking Layer- | Zinc Oxide | Zinc Oxide | Zinc Oxide | Zinc Oxide |
| 3^{rd} film | | | | |
| Metallic Layer | Silver | Silver | Silver | Silver |
| Primer Layer | Titanium | Titanium | Titanium | Titanium |
| Top Layer- | Zinc Stannate | Zinc Stannate | Zinc Stannate | Zinc Stannate |
| 1^{st} Film | | | | |
| Top Layer- | SiAlON | SiAlON | SiAlON | SiAlON |
| 2^{nd} film | | | | |
| Protective Film | N/A | SiAIN | N/A | SiAIN |

TABLE 5

| Sample No. | CE-6 | CE-7 |
|---|---|---|
| Substrate | Glass | Glass |
| 1^{st} dielectric film | Zinc Stannate | Zinc Stannate |
| 2^{nd} dielectric film | Zinc Oxide | Zinc Oxide |
| Metallic Layer | Silver | Silver |
| Primer Layer | Titanium | Titanium |
| Top Layer | Zinc Stannate | Zinc Stannate |
| 1^{st} Film | | |
| Top Layer | SiAlON | SiAlON |
| 2^{nd} film | | |
| Protective Film | N/A | SiAIN |

The resulting color properties of the coated articles can be found in Table 6.

TABLE 6

| | ΔEcmc | | |
|---|---|---|---|
| Sample | Rf | Rg | T |
| 3 | 1.59 | 3.25 | 1.26 |
| 4 | 2.24 | 3.01 | 2.59 |
| 5 | 1.23 | 1.75 | 1.04 |
| 6 | 3.35 | 2.85 | 2.84 |
| CE-6 | 4.71 | 4.36 | 1.35 |
| CE-7 | 6.27 | 5.37 | 1.64 |

### Example 3

Substrates were coated with a functional coating having a blocking layer. The substrate was glass. The functional coating included a blocking layer disposed over the substrate, where the blocking layer comprised a blocking film as the first film, a first metallic layer, a primer layer, a first middle layer, a second metallic layer, a second primer layer, a top layer, and a protective layer. The blocking film of the blocking layer comprised SiAlN (at thicknesses of 50 Å, 150 Å, or 300 Å), SiAlON (at thicknesses of 50 Å, 150 Å, or 300 Å), or SiAlO (at thicknesses of 150 Å, 200 Å, or 250 Å). The blocking layer further comprised a zinc stannate film as a second film and a zinc oxide film as a third film. The first metallic layer was disposed over the zinc oxide film of the blocking layer. The first metallic layer was a continuous silver layer. A first titanium primer layer was disposed over the first metallic layer, and a first middle layer was disposed over the first primer layer. The first middle layer comprised a first film comprising zinc oxide, a second film comprising zinc stannate, and a third film comprising zinc oxide. A second metallic layer was disposed over the first middle layer. The second metallic layer was a continuous silver layer. A second titanium primer layer was disposed over the second metallic layer. A top layer was disposed over the second primer layer. The top layer comprised a zinc stannate as a first film and a zinc oxide film as a second film. A protective layer comprising titanium dioxide was disposed over the top layer. A comparative example was prepared without a blocking film and had only a first and second dielectric film of zinc stannate and zinc oxide, respectively.

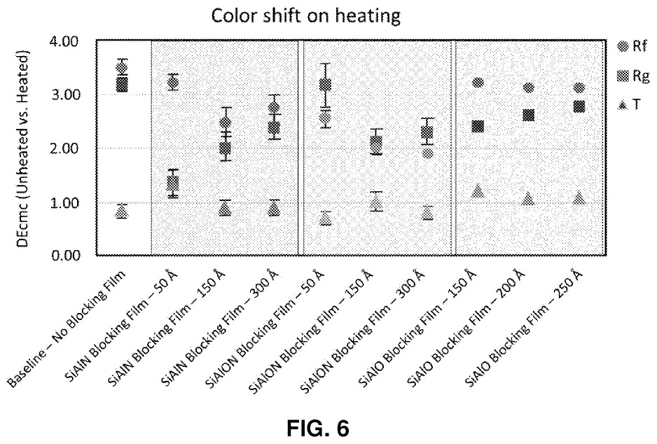

The resulting color properties of the coated substrates can be found in FIG. 6. A reduction in color shifts in both the Rf and Rg attributes were observed with the use of a blocking film.

### Example 4

Coated substrates were analyzed using X-Ray Photoelectron Spectroscopy (XPS). A baseline substrate with ZnSn on glass was prepared and analyzed using XPS. A sample substrate was prepared with a SiAlN blocking film on glass and ZnSn on the SiAlN blocking film. The sample substrate was analyzed using XPS. A second sample substrate was prepared with a SiAlON blocking film on glass and ZnSn on the SiAlON blocking film. The sample substrate was analyzed using XPS. In the baseline substrate, zinc migrated deep into the substrate and calcium migrated into the coating. In the sample substrates, the migration of zinc towards the glass substrate was reduced and the migration of calcium, magnesium, and sodium from the glass substrate into the coating stack was reduced.

### Example 5

Monolithic glass and insulated glass units (IGUs) were prepared using inventive coatings and baseline double, triple, or quadruple silver low e-coatings (without a blocking layer).

The baseline low e-coating had the following general structure: Glass/Dielectric/Metal Layer+Primer Layer/Dielectric Layer. The metal layers in the baseline low e-coatings are continuous metal layers and have at least 1 primer layer, or can have 2 primer layers.

For the monolithic glass of Example 7, an inventive coating was applied onto a clear glass substrate. For the monolithic glass of Comparative Example 8, a baseline coating was applied onto a clear glass substrate.

The IGU of Example 8 had the following structure:
Clear Glass
Air Gap
Clear glass with an inventive coating on the No. 3 surface.

The IGU of Comparative Example 9 had the following structure:
Clear Glass
Air Gap
Glass with a baseline coating on the No. 3 surface.

The IGU of Example 9 had the following structure:
Clear glass with a baseline coating on the No. 2 surface
Air Gap
Glass with an inventive coating on the No. 4 surface.

The IGU of Comparative Example 10 had the following structure:
Clear glass with a baseline coating on the No. 2 surface
Air Gap
Glass with a baseline coating on the No. 4 surface.

The resulting color properties of the baseline monolithic glass and IGUs can be found in Table 7.

TABLE 7

| | Estimated | | |
|---|---|---|---|
| Sample | T ΔEcmc | Rext ΔEcmc | Rint ΔEcmc |
| 7 | 1.05 | 2.09 | 2.01 |
| 8 | 0.95 | 1.40 | 2.02 |
| 9 | 0.79 | 1.28 | 1.62 |
| CE-8 | 0.83 | 3.21 | 3.50 |
| CE-9 | 0.82 | 2.09 | 2.54 |
| CE-10 | 0.64 | 1.93 | 2.87 |

### Example 6

An exemplary inventive coated article can be found in Table 8.

TABLE 8

| | | | Thickness |
|---|---|---|---|
| Structure | | Composition | (Å) |
| Glass | | | Any |
| Blocking Layer | Blocking Film | SiAlON | 250 |
| | 2^{nd} Film | Zinc Stannate | 100 |
| | 3^{rd} Film | Zinc Oxide | 80 |
| Metallic Layer | | Ag | 75 |
| Primer Layer | | Ti | 10 |
| Top Layer | 1^{st} Film | Zinc Oxide | 80 |
| | 2^{nd} Film | Zinc Stannate | 120 |
| | 3^{rd} Film | SiAlON | 200 |
| Protective Coating | 1^{st} Protective Film | SiAlN | 120 |
| | 2^{nd} Protective Film | TiAlO | 300 |

### Example 7

An exemplary inventive coated article can be found in Table 9.

TABLE 9

| | | | Thickness |
|---|---|---|---|
| Structure | | Composition | (Å) |
| Glass | | | Any |
| Blocking Layer | Blocking Film | SiAlON | 150 |
| | 2^{nd} Film | Zinc Stannate | 200 |
| | 3^{rd} Film | Zinc Oxide | 80 |
| Metallic Layer | | Ag | 75 |
| Primer Layer | | Ti | 10 |
| Top Layer | 1^{st} Film | Zinc Oxide | 80 |
| | 2^{nd} Film | Zinc Stannate | 120 |
| | 3^{rd} Film | SiAlON | 200 |
| Protective Coating | 1^{st} Protective Film | SiAlN | 120 |
| | 2^{nd} Protective Film | TiAlO | 300 |

### Example 8

An exemplary inventive coated article can be found in Table 10.

TABLE 10

| | | | Thickness |
|---|---|---|---|
| Structure | | Composition | (Å) |
| Glass | | | Any |
| Blocking Layer | Blocking Film | SiAlON | 200 |
| | 2^{nd} Film | Zinc Stannate | 150 |
| | 3^{rd} Film | Zinc Oxide | 80 |
| Metallic Layer | | Ag | 75 |
| Primer Layer | | Ti | 10 |
| Top Layer | 1^{st} Film | Zinc Oxide | 80 |
| | 2^{nd} Film | Zinc Stannate | 120 |
| | 3^{rd} Film | SiAlON | 200 |
| Protective Coating | 1^{st} Protective Film | SiAlN | 120 |
| | 2^{nd} Protective Film | TiAlO | 300 |

### Example 9

An exemplary inventive coated article can be found in Table 11.

TABLE 11

| | | | Thickness |
|---|---|---|---|
| Structure | | Composition | (Å) |
| Glass | | | Any |
| Blocking Layer | Blocking Film | SiAlON | 180 |
| | 2^{nd} Film | Zinc Stannate | 170 |
| | 3^{rd} Film | Zinc Oxide | 80 |
| Metallic Layer | | Ag | 75 |
| Primer Layer | | Ti | 10 |
| Top Layer | 1^{st} Film | Zinc Oxide | 80 |
| | 2^{nd} Film | Zinc Stannate | 120 |
| | 3^{rd} Film | SiAlON | 200 |
| Protective Coating | 1^{st} Protective Film | SiAlN | 120 |
| | 2^{nd} Protective Film | TiAlO | 300 |

### Example 10

An exemplary inventive coated article can be found in Table 12.

TABLE 12

| | | | Thickness |
|---|---|---|---|
| Structure | | Composition | (Å) |
| Glass | | | Any |
| Blocking Layer | Blocking Film | SiAlON | 150 |
| | 2^{nd} Film | Zinc Stannate | 200 |
| | 3^{rd} Film | Zinc Oxide | 80 |
| Metallic Layer | | Ag | 75 |
| Primer Layer | | Ti | 10 |
| Top Layer | 1^{st} Film | Zinc Oxide | 80 |
| | 2^{nd} Film | Zinc Stannate | 120 |
| | 3^{rd} Film | SiAlON | 160 |
| Protective Coating | 1^{st} Protective Film | SiAlN | 160 |
| | 2^{nd} Protective Film | TiAlO | 300 |

### Example 11

Glass substrates were coated with a blocking layer, where the blocking layer had a blocking film, zinc stannate as the second film, and zinc oxide as the third film. The blocking film was either SiAlN (at a thickness of 150 Å, 200 Å, or 300 Å) or SiAlON (at a thickness of 150 Å or 300 Å). The coated substrates were heated and the web rub durability was determined. Glass substrates coated with SiAlN blocking films having thicknesses of 150 Å and 200 Å had a reduced wet rub acceptability after heating. Glass substrates coated with a SiAlN blocking film having a thickness of 300 Å had a wet rub acceptability of 100%, before and after heating. Glass substrates coated with a SiAlON blocking film having a thickness of 150 Å had a wet red rub acceptability of 100% after heating. Glass substrates coated with a SiAlON blocking film having a thickness of 300 Å had a wet rub acceptability of 100%, before and after heating.

It will be readily appreciated by those skilled in the art that modifications may be made to the invention without departing from the concepts disclosed in the foregoing description. Accordingly, the particular embodiments described in detail herein are illustrative only and are not limiting to the scope of the invention, which is to be given the full breadth of the appended claims and any and all equivalents thereof.

What is claimed is:

1. A method of reducing red haze of a coated article, the method comprising:
providing a coated article comprising a first surface and second surface opposite the first surface, wherein the coated article comprises:
a blocking layer over at least a portion of the first surface or the second surface,
a metallic layer over at least a portion of the blocking layer, and
a top layer over at least a portion of the metallic layer; and
tempering the coated article,
wherein the coated article has reduced red haze after tempering.

2. The method of claim 1, wherein the blocking layer comprises a first film over at least a portion of the first surface or the second surface, a second film over at least a portion of the first film, and third film over at least a portion of the second film,
wherein the first film of the blocking layer is a blocking film.

3. The method of claim 2, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

4. The method of claim 2, wherein the optical index of refraction of the blocking film is at least 1.4 and not more than 2.3.

5. The method of claim 2, wherein the second film comprises zinc stannate and the third film comprises zinc oxide.

6. The method of claim 1, wherein the blocking layer comprises a total thickness of 150 Å to 850 Å.

7. The method of claim 1, wherein the coated article further comprises:
an optional primer layer over at least a portion of the metallic layer;
a first middle layer over at least a portion of the metallic layer or the optional primer layer;
a second metallic layer over at least a portion of the middle layer; and
an optional second primer layer over at least a portion of the second metallic layer,
wherein the top layer is over at least a portion of the second metallic layer or the optional second primer layer.

8. The method of claim 1, wherein the coated article comprises:
an optional primer layer over at least a portion of the metallic layer;
a first middle layer over at least a portion of the metallic layer or the optional primer layer;
a second metallic layer over at least a portion of the first middle layer;
an optional second primer layer over at least a portion of the second metallic layer;
a second middle layer over at least a portion of the second metallic layer or the optional second primer layer;
a third metallic layer over at least a portion of the second middle layer; and
an optional third primer layer over at least a portion of the third metallic layer,
wherein the top layer is over at least a portion of the third metallic layer or the optional third primer layer.

9. A method of making a coated article, the method comprising:
providing a coated article comprising a first surface and second surface opposite the first surface, wherein the coated article comprises:
a blocking layer over at least a portion of the first surface or the second surface,
a metallic layer over at least a portion of the blocking layer, and
a top layer over at least a portion of the metallic layer; and
tempering the coated article,
wherein the coated article has an optical color shift, as measured by ΔEcmc, of no more than 4.5 after tempering.

10. The method of claim 9, wherein the coated article has an optical color shift, as measured by ΔEcmc, of no more than 4.0 after tempering.

11. The method of claim 9, wherein the blocking layer comprises a first film over at least a portion of the first surface or the second surface, a second film over at least a portion of the first film, and third film over at least a portion of the second film,
wherein the first film of the blocking layer is a blocking film.

12. The method of claim 11, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.

13. The method of claim 11, wherein the optical index of refraction of the blocking film is at least 1.4 and not more than 2.3.

14. The method of claim 11, wherein the second film comprises zinc stannate and the third film comprises zinc oxide.

15. The method of claim 9, wherein the blocking layer comprises a total thickness of 150 Å to 850 Å.

16. The method of claim 9, wherein the coated article further comprises:
an optional primer layer over at least a portion of the metallic layer;
a first middle layer over at least a portion of the metallic layer or the optional primer layer;
a second metallic layer over at least a portion of the first middle layer; and
an optional second primer layer over at least a portion of the second metallic layer,
wherein the top layer is over at least a portion of the second metallic layer or the optional second primer layer.

17. The method of claim 9, wherein the coated article further comprises:
an optional primer layer over at least a portion of the metallic layer;
a first middle layer over at least a portion of the metallic layer or the optional primer layer;
a second metallic layer over at least a portion of the first middle layer;
an optional second primer layer over at least a portion of the second metallic layer;
a second middle layer over at least a portion of the second metallic layer or the optional second primer layer;
a third metallic layer over at least a portion of the second middle layer; and
an optional third primer layer over at least a portion of the third metallic layer,
wherein the top layer is over at least a portion of the third metallic layer or the optional third primer layer.

18. A method of reducing dendrite formation in a metallic layer of a coated article comprising:
providing a coated article comprising a first surface and second surface opposite the first surface, wherein the coated article comprises:
a blocking layer over at least a portion the first surface or the second surface,
a metallic layer over at least a portion of the blocking layer, and
a top layer over at least a portion of the metallic layer, thereby forming the coated article; and
tempering the coated article,
wherein the coated article has reduced dendrite formation in the metallic layer after tempering.

19. The method of claim 18, wherein the blocking layer comprises a first film over at least a portion of the first surface or the second surface, a second film over at least a portion of the first film, and third film over at least a portion of the second film,
wherein the first film of the blocking layer is a blocking film.

20. The method of claim 19, wherein the blocking film comprises silicon oxide, silicon aluminum oxide, silicon nitride, silicon aluminum nitride, silicon oxynitride, silicon aluminum oxynitride, titanium oxide, titanium aluminum oxide, or combinations thereof.
